(19) United States
(12) Patent Application Publication
(10) Pub. No.: US 2025/0351686 A1
(43) Pub. Date: Nov. 13, 2025

(54) DISPLAY DEVICE

(71) Applicant: Samsung Display Co., LTD., Yongin-si (KR)

(72) Inventors: Sang Hyun YUN, Yongin-si (KR); Jun Gi KIM, Yongin-si (KR); Youn Joo RYU, Yongin-si (KR); Jae Hun LEE, Yongin-si (KR); Hyun Young JUNG, Yongin-si (KR); Gwang Min CHA, Yongin-si (KR); Pil Soon HONG, Yongin-si (KR)

(21) Appl. No.: 18/979,114

(22) Filed: Dec. 12, 2024

(30) Foreign Application Priority Data
May 9, 2024 (KR) 10-2024-0061146

(51) Int. Cl. H10K 59/126; H10K 59/80

(52) U.S. Cl. CPC H10K 59/126; H10K 59/879

(57) ABSTRACT

A display device includes: a substrate; a light emitting element layer on the substrate and including light emitting elements; and a light control layer on the light emitting element layer and including: a louver layer and a louver support layer on the light emitting element layer and arranged alternately with each other; a first transmissive layer on the louver layer and the louver support layer; a first light blocking layer on the first transmissive layer and including light blocking patterns spaced apart from each other; a second transmissive layer on the first transmissive layer and the first light blocking layer; and a second light blocking layer on the second transmissive layer and including light blocking patterns spaced apart from each other, and wherein a height of the louver layer is greater than a height of the first light blocking layer and a height of the second light blocking layer.

### CROSS-REFERENCE TO RELATED APPLICATION

The present application claims priority to and the benefit of Korean Patent Application No. 10-2024-0061146, filed on May 9, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

As the information society develops, consumer demand for display devices for displaying images is increasing in various forms. Display devices may include displays such as liquid crystal displays (LCDs), field emission displays (FEDs), or light emitting displays (LEDs). Light emitting display may include an organic light emitting display device including an organic light emitting diode element as a light emitting element, or an inorganic light emitting display device including an inorganic light emitting diode element as a light emitting element.

In the case of vehicle display devices, when images are displayed on the vehicle display device located in front of a driver or passenger is reflected on a windshield at night, it may interfere with the driver's driving, and therefore, it may be desirable to control a viewing angle of the images displayed on the vehicle display device. In addition, in order to protect privacy, it may be desirable to control the viewing angle of the images displayed on the vehicle display device so that the images displayed on the vehicle display device located in front of the driver are not provided to the passenger.

The above information disclosed in this Background section is only for enhancement of understanding of the background and therefore the information discussed in this Background section does not necessarily constitute prior art.

### SUMMARY

Aspects of some embodiments of the present disclosure include a display device with relatively improved reliability of a light control layer.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes: a substrate, a light emitting element layer on the substrate and including a plurality of light emitting elements, and a light control layer on the light emitting element layer, wherein the light control layer includes, a louver layer and a louver support layer on the light emitting element layer and arranged alternately with each other, a first transmissive layer on the louver layer and the louver support layer, a first light blocking layer on the first transmissive layer and including a plurality of light blocking patterns spaced apart from each other, a second transmissive layer on the first transmissive layer and the first light blocking layer, and a second light blocking layer on the second transmissive layer and including a plurality of light blocking patterns spaced apart from each other, and wherein a height of the louver layer is greater than a height of the first light blocking layer and a height of the second light blocking layer.

According to some embodiments, the louver layer overlaps the plurality of light blocking patterns of the first light blocking layer and the plurality of light blocking patterns of the second light blocking layer.

According to some embodiments, the height of the louver layer is 3 to 30 times the height of the first light blocking layer and the height of the second light blocking layer, respectively.

According to some embodiments, the height of the louver layer is 30 μm or less.

According to some embodiments, the height of the first light blocking layer and the height of the second light blocking layer are each 1 μm to 5 μm

According to some embodiments, a height of the light control layer is 40 μm or more.

According to some embodiments, a width of the plurality of light blocking patterns of the first light blocking layer is smaller than a distance between the plurality of light blocking patterns of the first light blocking layer.

According to some embodiments, the width of the plurality of light blocking patterns of the first light blocking layer is 7 μm to 12 μm, and wherein the distance between the plurality of light blocking patterns of the first light blocking layer is 10 μm to 30 μm.

According to some embodiments, the louver layer includes a material different from the first light blocking layer and the second light blocking layer.

According to some embodiments, the louver layer includes at least one of an acrylate-based compound, an isocyanate-based compound, a polyamine-based compound such as polyethylene polyamine (PEPA) or polypropylene polyamine (PPPA), or an amide-based compound such as ethylenediamine, diethylenetriamine, and diethyltoluenediamine, and wherein the first light blocking layer and the second light blocking layer include at least one of propylene glycol methyl ether acetate, methacrylic acid-benzylmethacrylic acid copolymer, multi-functional acrylate, or a photo initiator.

According to some embodiments, the louver layer is formed by a coating process and a polishing process, and the first light blocking layer and the second light blocking layer are formed by a deposition process and a patterning process.

According to some embodiments, the louver support layer includes a material different from the first transmissive layer and the second transmissive layer.

According to some embodiments, the louver support layer includes an ester-based compound and a phosphine oxide compound, and wherein the first transmissive layer and the second transmissive layer include at least one of propylene glycol methyl ether acetate, methacrylic acid-benzylmethacrylic acid copolymer, multi-functional acrylate, or a photo initiator.

According to some embodiments, the louver support layer is formed by an inkjet printing process and a dry etching process, and wherein the first transmissive layer and the second transmissive layer are formed by a deposition process and a patterning process.

According to some embodiments, the display device may further comprise an overcoat layer on the second light blocking layer and the second transmissive layer, wherein the overcoat layer includes a material different from the louver support layer.

According to some embodiments, the overcoat layer includes at least one of propylene glycol methyl ether acetate, methacrylic acid-benzylmethacrylic acid copolymer, multi-functional acrylate, or a photo initiator.

According to some embodiments, the overcoat layer is formed by a deposition process and a patterning process.

According to some embodiments of the present disclosure, a display device includes: a substrate, a light emitting element layer on the substrate and including a plurality of light emitting elements, and a light control layer on the light emitting element layer, wherein the light control layer includes, a first transmissive layer on the light emitting element layer, a first light blocking layer on the first transmissive layer and including a plurality of light blocking patterns spaced apart from each other, a second transmissive layer on the first transmissive layer and the first light blocking layer, a second light blocking layer on the second transmissive layer and including a plurality of light blocking patterns spaced apart from each other, and wherein a louver layer and a louver support layer on the light emitting element layer and arranged alternately with each other, wherein the louver layer and the louver support layer are below the first light blocking layer, between the first light blocking layer and the second light blocking layer, or above the second light blocking layer, and wherein a height of the louver layer is greater than a height of the first light blocking layer and a height of the second light blocking layer.

According to some embodiments, the display device may further comprise a light transmissive lower film on the light emitting element layer, wherein the light transmissive lower film is directly below the first transmissive layer, or directly below the louver layer and the louver support layer.

According to some embodiments, the light transmissive lower film includes a material different from the louver support layer.

According to some embodiments, the louver support layer includes an ester-based compound and a phosphine oxide compound, and wherein the light transmissive lower film includes at least one of propylene glycol methyl ether acetate, methacrylic acid-benzylmethacrylic acid copolymer, multi-functional acrylate, or a photo initiator.

According to some embodiments of the present disclosure, a display device includes: a substrate, a light emitting element layer on the substrate and including a plurality of light emitting elements, and a light control layer on the light emitting element layer, wherein the light control layer includes, a louver layer and a louver support layer on the light emitting element layer and arranged alternately with each other, a first transmissive layer on the louver layer and the louver support layer, a first light blocking layer on the first transmissive layer and including a plurality of light blocking patterns spaced apart from each other, and an optical layer on the louver layer and the louver support layer, or on the first transmissive layer and the first light blocking layer, a height of the louver layer is greater than a height of the first light blocking layer, and the optical layer includes a plurality of optical patterns respectively between the plurality of light blocking patterns.

According to some embodiments, the plurality of optical patterns include a converging lens.

According to some embodiments, the plurality of optical patterns include a convex lens that is convex toward a display surface.

According to some embodiments, the plurality of optical patterns include at least one of a lenticular lens array or a micro lens array.

According to some embodiments, each of the plurality of optical patterns at least partially overlaps the plurality of light blocking patterns.

According to some embodiments, a width of each of the plurality of optical patterns is greater than a distance between the plurality of light blocking patterns.

According to some embodiments, each of the plurality of optical patterns does not overlap the plurality of light blocking patterns.

According to some embodiments, a width of each of the plurality of optical patterns is smaller than a distance between the plurality of light blocking patterns.

According to some embodiments, a refractive index of the optical layer is greater than a refractive index of the first transmissive layer and a refractive index of the first light blocking layer.

According to some embodiments, the refractive index of the optical layer is 1.6 or more, and the refractive index of the first transmissive layer and the first light blocking layer are each 1.5 or less.

According to some embodiments of the present disclosure, an electronic device includes a display device, the display device including, a substrate, a light emitting element layer on the substrate and including a plurality of light emitting elements, and a light control layer on the light emitting element layer, wherein the light control layer includes, a louver layer and a louver support layer on the light emitting element layer and arranged alternately with each other, a first transmissive layer on the louver layer and the louver support layer, a first light blocking layer on the first transmissive layer and including a plurality of light blocking patterns spaced apart from each other, a second transmissive layer on the first transmissive layer and the first light blocking layer, and a second light blocking layer on the second transmissive layer and including a plurality of light blocking patterns spaced apart from each other, and wherein a height of the louver layer is greater than a height of the first light blocking layer and a height of the second light blocking layer.

According to some embodiments of the present disclosure, an electronic device includes a display device, the display device including, a substrate, a light emitting element layer on the substrate and including a plurality of light emitting elements, and a light control layer on the light emitting element layer, wherein the light control layer includes, a first transmissive layer on the light emitting element layer, a first light blocking layer on the first transmissive layer and including a plurality of light blocking patterns spaced apart from each other, a second transmissive layer on the first transmissive layer and the first light blocking layer, a second light blocking layer on the second transmissive layer and including a plurality of light blocking patterns spaced apart from each other, and wherein a louver layer and a louver support layer on the light emitting element layer and arranged alternately with each other, wherein the louver layer and the louver support layer are below the first light blocking layer, between the first light blocking layer and the second light blocking layer, or above the second light blocking layer, and wherein a height of the louver layer is greater than a height of the first light blocking layer and a height of the second light blocking layer.

According to some embodiments of the present disclosure, an electronic device includes a display device, the display device including, a substrate, a light emitting element layer on the substrate and including a plurality of light emitting elements, and a light control layer on the light emitting element layer, wherein the light control layer includes, a louver layer and a louver support layer on the light emitting element layer and arranged alternately with each other, a first transmissive layer on the louver layer and the louver support layer, a first light blocking layer on the first transmissive layer and including a plurality of light blocking patterns spaced apart from each other, and an optical layer on the louver layer and the louver support layer, or on the first transmissive layer and the first light blocking layer, a height of the louver layer is greater than a height of the first light blocking layer, and the optical layer includes a plurality of optical patterns respectively between the plurality of light blocking patterns.

In a display device according to some embodiments of the present disclosure, the reliability of the light control layer may be relatively improved.

However, the characteristics of embodiments according to the present disclosure are not restricted to those set forth herein. The above and other characteristics of the embodiments will become more apparent to one of ordinary skill in the art to which the embodiments pertain by referencing the appended claims, and their equivalents.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating a display device according to some embodiments;

FIG. 3 is a schematic cross-sectional view of the display device taken along the line X1-X1′ of FIG. 2;

FIG. 4 is a schematic view when the display device according to some embodiments is applied to a vehicle;

FIG. 5 is a cross-sectional view illustrating an example of a display panel according to some embodiments;

FIG. 6 is a plan view illustrating a portion of a display area according to some embodiments;

FIG. 7 is a cross-sectional view taken along the line X2-X2′ of FIG. 6;

FIG. 8 is a schematic view illustrating a viewing angle of a display device according to a comparative example;

FIG. 9 is a schematic view illustrating a viewing angle of the display device according to the embodiments of FIG. 7;

FIG. 10 is a cross-sectional view illustrating a display panel according to some embodiments;

FIG. 11 is a cross-sectional view illustrating a display panel according to some embodiments;

FIG. 12 is a cross-sectional view illustrating a display panel according to some embodiments;

FIG. 13 is a cross-sectional view illustrating a display panel according to some embodiments;

FIG. 14 is a cross-sectional view illustrating a display panel according to some embodiments;

FIG. 15 is a schematic view illustrating a viewing angle of a display device according to embodiments illustrated in FIG. 13;

FIG. 16 is a schematic view illustrating a viewing angle of a display device according to embodiments illustrated in FIG. 14;

FIG. 17 is a cross-sectional view illustrating a display panel according to some embodiments; and

FIG. 18 is a cross-sectional view illustrating a display panel according to some embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will more fully convey the scope of embodiments according to the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

Hereinafter, aspects of some embodiments will be described with reference to the accompanying drawings.

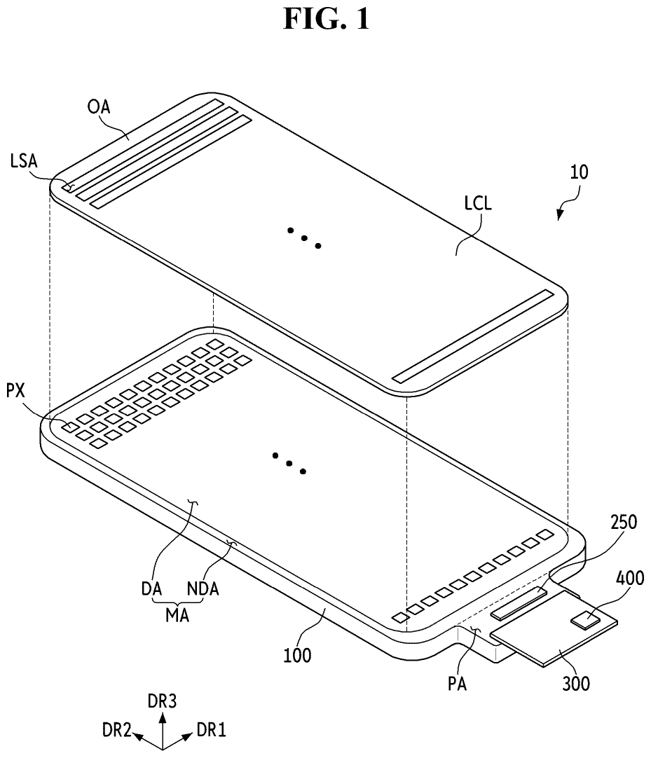

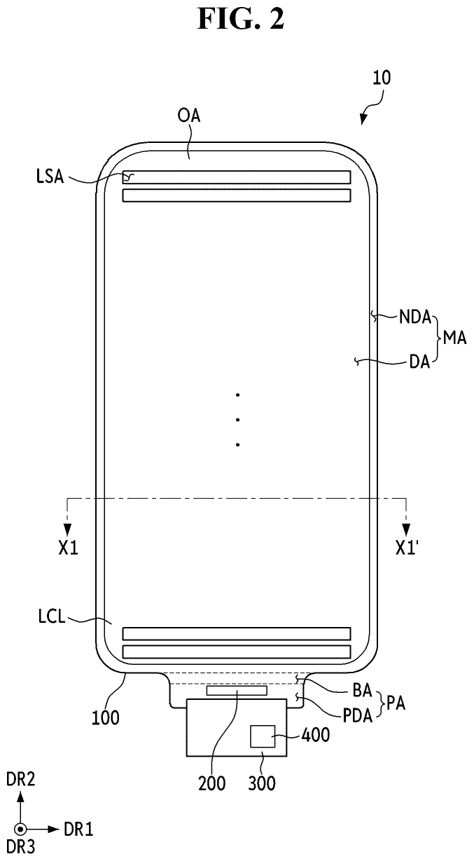

FIG. 1 is a perspective view illustrating a display device according to some embodiments. FIG. 2 is a plan view illustrating a display device according to some embodiments.

Referring to FIGS. 1 and 2, a display device 10 is a device that displays moving images (e.g., video images) or still images (e.g., static images), and may be used as a display screen of each of various products such as a vehicle, a television, a laptop computer, a monitor, a billboard, and Internet of Things (IOT) as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC).

According to some embodiments, when the display device 10 is used as a display screen for a vehicle, the display device 10 may be a vehicle display. The vehicle display may provide users with various service information such as convenience functions, media information, etc., as well as information about vehicle operation information and status information. When the display device 10 includes an input device such as a touch panel, the user may manipulate various functions such as a driving mode of the vehicle and convenience functions through the display device 10.

The display device 10 may be any one of an organic light emitting display device, a liquid crystal display device, a plasma display device, a field emission display device, an electrophoretic display device, an electrowetting display device, a quantum dot light emitting display device, and a micro LED display device. Hereinafter, it is mainly described that the display device 10 is the organic light emitting display device, but embodiments according to the present disclosure are not limited thereto.

The display device 10 according to some embodiments may include a display panel 100, a display driving circuit 250, a circuit board 300, and a touch driving circuit 400.

The display panel 100 may include a plurality of pixels PX arranged in a first direction DR1 and a second direction DR2 (e.g., in a plurality of columns and a plurality of rows of pixels PX). Each of the pixels PX may have a planar shape such as a rectangle, a square, or a rhombus. For example, as illustrated in the drawing, each of the pixels PX may have a planar shape such as a square. However, each of the pixels PX is not limited thereto, and may have various shapes such as a polygon, a circle, and an ellipse in a plan view.

In the illustrated drawings, the first direction DR1 and the second direction DR2 are horizontal directions and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. In the present specification, a direction indicated by the first to third directions DR1, DR2, and DR3 in the drawing may be referred to as one side, and an opposite direction may be referred to as the other side, and unless otherwise specified, may include both sides.

Unless otherwise defined, in the present specification, directions indicated by arrows in the first to third directions DR1, DR2, and DR3 may be referred to as one side, and the opposite directions thereof may be referred to as the other side. In addition, in the present specification, “on”, “upper side”, “upper portion”, “top”, and “upper surface” refer to a direction in which an arrow in the drawing is directed in a third direction DR3 based on the drawing, and “below”, “lower side”, “lower portion”, “bottom”, and “lower surface” refer to a direction opposite to the direction in which the arrow in the third direction DR3 is directed based on the drawing.

The display panel 100 may include a main area MA and a protruding area PA protruding from one side of the main area MA.

The main area MA may be formed in a rectangular plane having short sides in the first direction DR1 and long sides in the second direction DR2 intersecting the first direction DR1. A corner where the short side in the first direction DR1 and the long side in the second direction DR2 meet may be rounded to have a curvature (e.g., a set or predetermined curvature) or may be formed at a right angle. The planar shape of the display device 10 is not limited to a quadrangular shape, and may be formed in other polygonal, circular, or oval shapes. The main area MA may be formed to be flat, but is not limited thereto, and may include curved portions formed at left and right ends. In this case, the curved portion may have a constant curvature or a changing curvature.

The main area MA may include a display area DA in which pixels are formed to display images, and a non-display area NDA which is a peripheral area of (e.g., surrounding or outside a footprint of) the display area DA.

In the display area DA, not only pixels but also scan lines, data lines, and power lines connected to the pixels may be located. When the main area MA includes the curved portion, the display area DA may be located on the curved portion. In this case, the image of the display panel 100 may be viewed even on the curved portion.

The non-display area NDA may be defined as an area from the outside of the display area DA to an edge of the display panel 100. A scan driver for applying scan signals to the scan lines and link lines connecting the data lines and the display driving circuit 250 may be located in the non-display area NDA.

The protruding area PA may protrude from one side of the main area MA. For example, the protruding area PA may protrude from a lower side of the main area MA as illustrated in FIG. 2. A length of the protruding area PA in the first direction DR1 may be smaller than a length of the main area MA in the first direction DR1.

The protruding area PA may include a bending area BA and a pad area PDA. In this case, the pad area PDA may be located on one side of the bending area BA, and the main area MA may be located on the other side of the bending area BA. For example, the pad area PDA may be located on a lower side of the bending area BA, and the main area MA may be located on an upper side of the bending area BA.

The display panel 100 may be flexibly formed to be curved, bent, folded, or rolled. Therefore, the display panel 100 may be bent in a thickness direction, that is, in a third direction DR3, in the bending area BA. In this case, before the display panel 100 is bent, one surface of the pad area PDA of the display panel 100 faces upward, but after the display panel 100 is bent, one surface of the pad area PDA of the display panel 100 faces downward. As a result, because the pad area PDA is located on a lower side of the main area MA, the pad area PDA may overlap the main area MA.

Pads electrically connected to the display driving circuit 250 and the circuit board 300 may be located in the pad area PDA of the display panel 100.

The display driving circuit 250 outputs signals and voltages for driving the display panel 100. For example, the display driving circuit 250 may supply data voltages to the data lines. In addition, the display driving circuit 250 may supply power voltage to the power line and scan control signals to a scan driver. The display driving circuit 250 may be formed as an integrated circuit (IC) and be attached onto the display panel 100 in the pad area PDA using a chip on glass (COG) method, a chip on plastic (COP) method, or an ultrasonic bonding method, but embodiments according to the present disclosure are not limited thereto. For example, the display driving circuit 250 may be mounted on the circuit board 300.

The pads may include display pads electrically connected to the display driving circuit 250 and touch pads electrically connected to the touch lines.

The circuit board 300 may be attached onto the pads using an anisotropic conductive film. Accordingly, lead lines of the circuit board 300 may be electrically connected to the pads. The circuit board 300 may be a flexible printed circuit board, a printed circuit board, or a flexible film such as a chip on film.

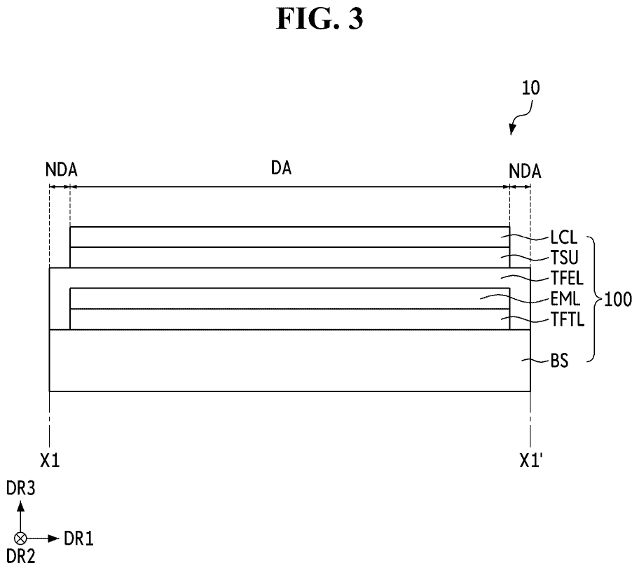

The touch driving circuit 400 may be connected to touch electrodes of a touch sensor layer TSU (see FIG. 3) of the display panel 100. The touch driving circuit 400 applies driving signals to the touch electrodes of the touch sensor layer TSU (see FIG. 3) and measures capacitance values of the touch electrodes. The driving signal may be a signal having a plurality of driving pulses. The touch driving circuit 400 may not only determine whether a touch is input but also calculate touch coordinates where a touch is input, based on the capacitance values.

The touch driving circuit 400 may be located on the circuit board 300. The touch driving circuit 400 may be formed as an integrated circuit (IC) and mounted on the circuit board 300.

In the display device 10 according to some embodiments, the display panel 100 may further include a light control layer LCL.

The light control layer LCL may be directly located on the main area MA of the display panel 100. For example, the light control layer LCL may be embedded in the display panel 100 and directly located on the main area MA of the display panel 100. As the light control layer LCL is embedded in the display panel 100, the thickness and manufacturing cost of the display device 10 may be relatively reduced compared to when a separate light control film is attached.

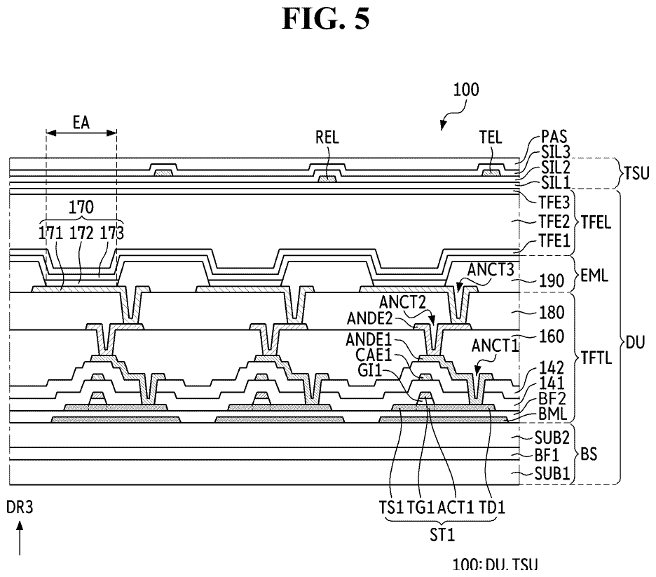

According to some embodiments, the light control layer LCL may be located on the display area DA of the main area MA. The light control layer LCL may control a viewing angle of light emitted from a light emitting layer 172 (see FIG. 5) of the display panel 100.

However, embodiments according to the present disclosure are not limited thereto, and a size of the light control layer LCL in a plan view may be greater than a size of the display area DA. In this case, the light control layer LCL may overlap both the display area DA and the non-display area NDA.

According to some embodiments, the light control layer LCL may include a transmissive area OA and a non-transmissive area LSA.

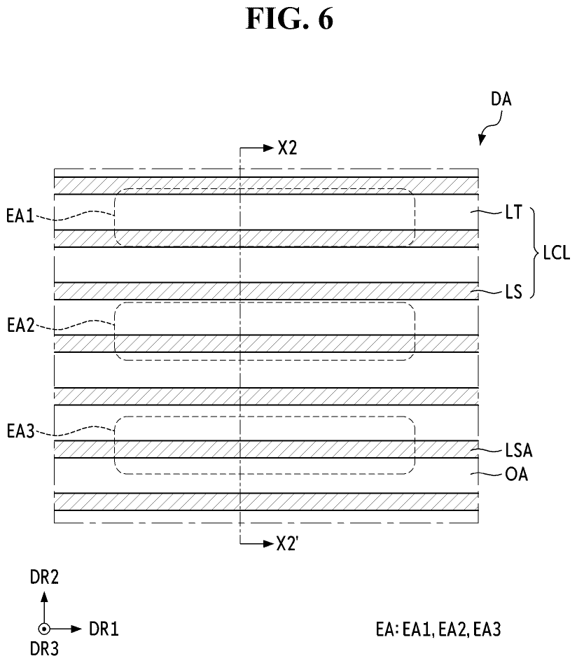

The transmissive area OA may be an area in which a light blocking film LS (see FIG. 6) is not located. The transmissive area OA, which is an area that transmits light, may extend along the third direction DR3.

The transmissive area OA may have a quadrangular shape in a plan view as illustrated in FIGS. 1 and 2, but embodiments according to the present disclosure are not limited thereto. The transmissive area OA may have a circular, oval, or polygonal shape in a plan view. According to some embodiments, the shape of the transmissive area OA may correspond (or substantially correspond) to the shape of the display panel 100.

The non-transmissive areas LSA may be remaining areas of the light control layer LCL excluding the transmissive area OA. The non-transmissive areas LSA may be areas in which the light blocking film LS (see FIG. 6) is located.

According to some embodiments, the non-transmissive areas LSA may extend in the first direction DR1 or the second direction DR2. As an example, as illustrated in FIG. 1, the non-transmissive area LSA may extend in the first direction DR1 and be arranged along the second direction DR2. As another example, the non-transmissive area LSA may extend in the second direction DR2 and be arranged along the first direction DR1. As still another example, some of the non-transmissive areas LSA may extend in the first direction DR1 and be arranged along the second direction DR2, and the remaining portion of the non-transmissive areas LSA may extend in the second direction DR2 and be arranged along the first direction DR1.

According to some embodiments, as illustrated in FIG. 1, when the non-transmissive areas LSA are arranged along the second direction DR2, the viewing angle may be controlled in the second direction DR2. According to some embodiments, when the non-transmissive areas LSA are arranged along the first direction DR1, the viewing angle may be controlled in the first direction DR1. In the display device 10 according to some embodiments, the arrangement and shape of the transmissive area OA and the non-transmissive area LSA may be variously changed depending on the required control direction of the viewing angle.

Meanwhile, it is illustrated in the drawings that the transmissive area OA is arranged to surround the non-transmissive areas LSA, but the present disclosure is not limited thereto. According to some embodiments, the transmissive area OA may include a plurality of transmissive areas OA, and the plurality of transmissive areas OA extend in the same direction as the non-transmissive areas LSA, so that the plurality of transmissive areas OA and non-transmissive areas LSA may be arranged to alternate with each other. For example, as illustrated in FIG. 1, when the non-transmissive areas LSA extend in the first direction DR1, the transmissive areas OA may extend in the first direction DR1 and may be arranged to alternate with the non-transmissive areas LSA in the second direction DR2.

The light control layer LCL may include a light blocking film LS (see FIG. 6) that blocks light emitted from a light emitting layer 172 (see FIG. 5) of the display panel 100 and a light transmissive film LT (see FIG. 6) that transmits the light. The detailed structure of the light control layer LCL will be described later with reference to FIG. 6 and the like.

FIG. 3 is a schematic cross-sectional view of the display device taken along the line X1-X1′ of FIG. 2.

Referring to FIG. 3, the display device 10 may include a display panel 100 in which the light control layer LCL is embedded. The display panel 100 may include a base member BS, a thin film transistor layer TFTL, a light emitting element layer EML, a thin film encapsulation layer TFEL, a touch sensor layer TSU, and a light control layer LCL.

The base member BS may include a substrate. The substrate may be made of an insulating material such as glass, quartz, or a polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. Alternatively, the substrate may also include a metal material.

The substrate may be a rigid substrate or may be a flexible substrate that may be bent, folded, and rolled. When the substrate is the flexible substrate, the substrate may be formed of polyimide PI, but embodiments according to the present disclosure are not limited thereto.

The thin film transistor layer TFTL may be located on the base member BS. In the thin film transistor layer TFTL, scan lines, data lines, power lines, scan control lines, and routing lines connecting the pads and the data lines as well as thin film transistors of each of the pixels may be formed. Each of the thin film transistors may include a gate electrode, a semiconductor layer, a source electrode, and a drain electrode.

The thin film transistor layer TFTL may be located in the display area DA and the non-display area NDA. For example, the thin film transistors of each of the pixels, the scan lines, the data lines, and the power lines of the thin film transistor layer TFTL may be located in the display area DA. The scan control lines and link lines of the thin film transistor layer TFTL may be located in the non-display area NDA.

The light emitting element layer EML may be located on the thin film transistor layer TFTL. The light emitting element layer EML may include pixels including a first electrode, a light emitting layer, and a second electrode, and a pixel defining film defining the pixels. The light emitting layer may be an organic light emitting layer including an organic material. In this case, the light emitting layer may include a hole transporting layer, an organic light emitting layer, and an electron transporting layer. When a voltage (e.g., a set or predetermined voltage) is applied to the first electrode and a cathode voltage is applied to the second electrode through the thin film transistor of the thin film transistor layer TFTL, holes and electrons move to the organic light emitting layer through the hole transporting layer and the electron transporting layer, respectively, and are bonded to each other in the organic light emitting layer to emit light. The pixels of the light emitting element layer EML may be located in the display area DA.

The thin film encapsulation layer TFEL may be located on the light emitting element layer EML. The thin film encapsulation layer TFEL may serve to prevent or reduce instances of contaminants such as oxygen or moisture permeating into the light emitting element layer EML. To this end, the thin film encapsulation layer TFEL may include at least one inorganic film. The inorganic film may be a silicon nitride layer, a silicon oxynitride layer, a silicon oxide layer, a titanium oxide layer, or an aluminum oxide layer, but is not limited thereto. In addition, the thin film encapsulation layer TFEL may serve to protect the light emitting element layer EML from foreign substances such as dust. To this end, the thin film encapsulation layer TFEL may include at least one organic film. The organic film may be made of an acrylic resin, an epoxy resin, a phenolic resin, a polyamide resin, or a polyimide resin, but is not limited thereto.

The thin film encapsulation layer TFEL may be located in both the display area DA and the non-display area NDA. For example, the thin film encapsulation layer TFEL may be arranged to cover the light emitting element layer EML of the display area DA and the non-display area NDA, and cover the thin film transistor layer TFTL of the non-display area NDA.

The touch sensor layer TSU may be located on the thin film encapsulation layer TFEL. As the touch sensor layer TSU is directly located on the thin film encapsulation layer TFEL, the thickness of the display device 10 may be relatively reduced as compared to when a separate touch panel including the touch sensor layer TSU is attached onto the thin film encapsulation layer TFEL.

The touch sensor layer TSU may include touch electrodes for sensing a user's touch in a capacitance method, and touch lines connecting the pads and the touch electrodes. For example, the touch sensor layer TSU may sense a user's touch in a self-capacitance method or a mutual capacitance method.

The touch electrodes of the touch sensor layer TSU may be located in a touch sensor area overlapping the display area DA. The touch lines of the touch sensor layer TSU may be located in a touch peripheral area overlapping the non-display area NDA.

A light control layer LCL may be located on the touch sensor layer TSU. The light control layer LCL may be arranged to overlap display area DA. The light control layer LCL may serve to absorb or block light that travels beyond a certain angle with respect to the third direction DR3 among the light emitted from the light emitting element layer EML. That is, the light control layer LCL may control the viewing angle.

According to some embodiments, the display device 10 may further include a cover window. The cover window may be additionally located on the light control layer LCL. In this case, the light control layer LCL and the cover window may be attached by a transparent adhesive member such as an optically clear adhesive (OCA) film.

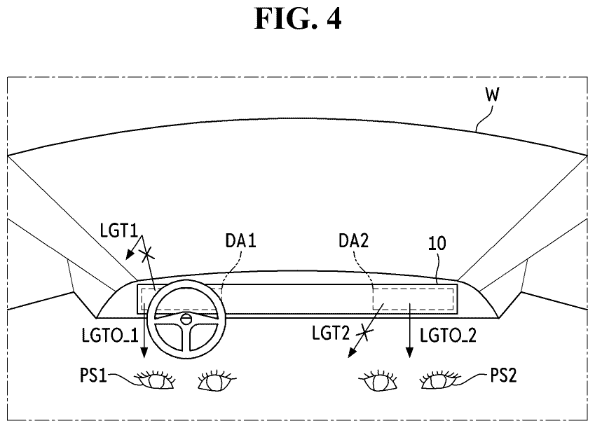

FIG. 4 is a schematic view when the display device according to some embodiments is applied to a vehicle.

Referring to FIG. 4, the display device 10 according to some embodiments may be, for example, a display device applied to a vehicle. The vehicle may include a body forming an exterior of the vehicle and an interior space defined by the body. The body may include a windshield W that protects a driver PS1 and a passenger PS2 from the outside and provides visibility to the driver PS1. As illustrated in the drawing, the display device 10 may be provided in the interior space.

According to some embodiments, the display device 10 may be located on a dashboard provided in the interior space. As an example, as illustrated in FIG. 4, the display device 10 may extend from the dashboard positioned in front of a driver's seat to the dashboard positioned in front of a passenger seat. For example, the display device 10 may be an integrated display connected from the dashboard positioned in front of the driver's seat to the dashboard positioned in front of the passenger seat.

In this case, the display device 10 may include a first display area DA1 positioned in front of the driver's seat and a second display area DA2 positioned in front of the passenger seat. The first display area DA1 may be located on the dashboard in front of the driver's seat and provide speed information, etc. to the driver PS1, and the second display area DA2 may be located on the dashboard in front of the passenger seat and provide entertainment information, etc. to the passenger PS2. According to some embodiments, the display device 10 may further include a third display area between the first display area DA1 and the second display area DA2.

As another example, the display device 10 may be located on the dashboard in front of the driver's seat and the dashboard in front of the passenger seat, respectively. For example, a first display device may be located on the dashboard in front of the driver's seat, and a second display device may be located on the dashboard in front of the passenger seat.

The driver PS1 may recognize (or visually recognize) a display screen of the display device 10 through light LGT0_1 emitted from the display device 10 towards the driver PS1. However, some light LGT1 among the light emitted from the display device 10 in front of the driver's seat may be reflected on the surrounding windshield W and provided to the driver PS1. In this case, the image displayed on the windshield W may interfere with the driving of the driver PS1. On the other hand, in the case of the display device 10 according to some embodiments, it may be possible to prevent in advance that some light LGT1 of the light emitted from the display device 10 in front of the driver's seat is reflected on the surrounding windshield W and provided to the driver PS1 by adjusting a viewing angle, especially a vertical viewing angle, with respect to a front direction (direction facing the driver PS1) of the light emitted from the display device 10.

The passenger PS2 may recognize (or visually recognize) a display screen of the display device 10 through light LGT0_2 emitted from the display device 10 towards the passenger PS2. However, some light LGT2 of the light emitted from the display device 10 in front of the passenger seat may be provided toward the driver PS1. In this case, when the vehicle is driving, the viewing of the driver PS1 may be restricted for reasons such as safety. In the case of the display device 10 according to some embodiments, it may be possible to prevent some light LGT2 of the light emitted from the display device 10 in front of the passenger seat from being provided to the driver by adjusting the viewing angle, especially the left and right viewing angles, with respect to the front direction (direction facing the passenger PS2) of the light emitted from the display device 10.

It is illustrated in the drawing that the display device 10 in front of the driver's seat adjusts the vertical viewing angle, and the display device 10 in front of the passenger seat adjusts the left and right viewing angle, but embodiments according to the present disclosure are not limited thereto. As an example, the display device 10 in front of the driver's seat may also adjust the right and left viewing angle, and the display device 10 in front of the passenger seat may also adjust the vertical viewing angle. As another example, the display device 10 in front of the driver's seat and the display device 10 in front of the passenger seat may also adjust both the vertical viewing angle and the left and right viewing angle, respectively.

The viewing angle may be adjusted through the light control layer LCL. The viewing angle may be limited to an angle range (e.g., a set or predetermined angle range) through the light control layer LCL. As an example, when an imaginary line facing the driver PS1 or passenger PS2 in the front direction and extending in a direction perpendicular to the display surface of the display device 10 is taken as a normal line, the viewing angle may be an angle within 35° from the normal line. According to some embodiments, the angle within 35° from the normal line may be defined as an effective viewing angle, but is not limited thereto.

FIG. 5 is a cross-sectional view illustrating an example of a display panel according to some embodiments.

Referring to FIG. 5, the display panel 100 may include a display layer DU and a touch sensor layer TSU. The display layer DU may include a base member BS, a thin film transistor layer TFTL, a light emitting element layer EML, and a thin film encapsulation layer TFEL.

The base member BS may include a first substrate SUB1, a first buffer film BF1 located on the first substrate SUB1, and a second substrate SUB2 located on the first buffer film BF1.

The first substrate SUB1 and the second substrate SUB2 may be made of an insulating material such as glass, quartz, or polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. Alternatively, the substrate may also include a metal material.

The first substrate SUB1 and the second substrate SUB2 may be rigid substrates or flexible substrates that may be bent, folded, and rolled. When the substrate is the flexible substrate, the substrate may be formed of polyimide PI, but is not limited thereto.

The first buffer film BF1 is a film for protecting a first thin film transistor ST1 and a light emitting layer 172 from moisture permeating through the first and second substrates SUB1 and SUB2, which are vulnerable to moisture permeation. The first buffer film BF1 may be formed of a plurality of inorganic films alternately stacked. For example, the first buffer film BF1 may be formed of a multi-film in which one or more inorganic films of a silicon nitride layer, a silicon oxynitride layer, a silicon oxide layer, a titanium oxide layer, and an aluminum oxide layer are alternately stacked.

The thin film transistor layer TFTL may include a lower metal layer BML, a second buffer film BF2, a first thin film transistor ST1, a first gate insulating film GI1, a first interlayer insulating film 141, a first capacitor electrode CAE1, a second interlayer insulating film 142, a first anode connection electrode ANDE1, a first organic film 160, a second anode connection electrode ANDE2, and a second organic film 180.

The lower metal layer BML may be located on the second substrate SUB2. The lower metal layer BML may be arranged to overlap a first active layer ACT1 of the first thin film transistor ST1 in the third direction DR3 to prevent or reduce leakage current from occurring when light is incident on the first active layer ACT1 of the first thin film transistor ST1. The lower metal layer BML may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof. The lower metal layer BML may be omitted.

The second buffer film BF2 may be located on the lower metal layer BML. The second buffer film BF2 is a film for protecting the first thin film transistor ST1 and the light emitting layer 172 from moisture permeating through the first and second substrates SUB1 and SUB2, which are vulnerable to moisture permeation. The second buffer film BF2 may be formed of a plurality of inorganic films alternately stacked. For example, the second buffer film BF2 may be formed of a multi-film in which one or more inorganic films of a silicon nitride layer, a silicon oxynitride layer, a silicon oxide layer, a titanium oxide layer, and an aluminum oxide layer are alternately stacked.

The first active layer ACT1 of the first thin film transistor ST1 may be located on the second buffer film BF2. The first active layer ACT1 of the first thin film transistor ST1 includes polycrystalline silicon, single crystal silicon, low-temperature polycrystalline silicon, amorphous silicon, or an oxide semiconductor. The first active layer ACT1 of the first thin film transistor ST1 exposed and not covered by the first gate insulating film GI1 may be doped with impurities or ions to have conductivity. Therefore, a first source electrode TS1 and a first drain electrode TD1 of the first active layer ACT1 of the first thin film transistor ST1 may be formed.

The first gate insulating film GI1 may be located on the first active layer ACT1 of the first thin film transistor ST1. It is illustrated in FIG. 5 that the first gate insulating film GI1 is located between a first gate electrode TG1 and the first active layer ACT1 of the first thin film transistor ST1, but the present disclosure is not limited thereto. The first gate insulating film GI1 may also be located between the first interlayer insulating film 141 and the first active layer ACT1 and between the first interlayer insulating film 141 and the second buffer film BF2. The first gate insulating film GI1 may be formed of an inorganic film, for example, a silicon nitride layer, a silicon oxynitride layer, a silicon oxide layer, a titanium oxide layer, or an aluminum oxide layer.

The first gate electrode TG1 of the first thin film transistor ST1 may be located on the first gate insulating film GI1. The first gate electrode TG1 of the first thin film transistor ST1 may overlap the first active layer ACT1 in the third direction DR3. The first gate electrode TG1 of the first thin film transistor ST1 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first interlayer insulating film 141 may be located on the first gate electrode TG1 of the first thin film transistor ST1. The first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

The first capacitor electrode CAE1 may be located on the first interlayer insulating film 141. The first capacitor electrode CAE1 may overlap the first gate electrode TG1 of the first thin film transistor ST1 in a third direction (Z-axis direction). Because the first interlayer insulating film 141 has a dielectric constant (e.g., a set or predetermined dielectric constant), a capacitor may be formed by the first capacitor electrode CAE1, the first gate electrode TG1, and the first interlayer insulating film 141 located between the first capacitor electrode CAE1 and the first gate electrode TG1. The first capacitor electrode CAE1 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second interlayer insulating film 142 may be located on the first capacitor electrode CAE1. The second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

A first anode connection electrode ANDE1 may be located on the second interlayer insulating film 142. The first anode connection electrode ANDE1 may be connected to the first drain electrode TD1 of the first thin film transistor ST1 through a first anode contact hole ANCT1 penetrating through the first interlayer insulating film 141 and the second interlayer insulating film 142 to expose the first drain electrode TD1 of the first thin film transistor ST1. The first anode connection electrode ANDE1 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first organic film 160 for planarization may be located on the first pixel connection electrode ANDE1. The first organic film 160 may be formed of an organic film made of an acryl resin, an epoxy resin, a phenolic resin, a polyamide resin, a polyimide resin, or the like.

The second anode connection electrode ANDE2 may be located on the first organic film 160. The second anode connection electrode ANDE2 may be connected to the first anode connection electrode ANDE1 through a second anode contact hole ANCT2 penetrating through the first organic film 160 to expose the first anode connection electrode ANDE1. The second anode connection electrode ANDE2 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second organic film 180 may be located on the second anode connection electrode ANDE2. The second organic film 180 may be formed of an organic film made of an acryl resin, an epoxy resin, a phenolic resin, a polyamide resin, a polyimide resin, or the like.

It is illustrated in FIG. 5 that the first thin film transistor ST1 is formed in a top gate type in which the first gate electrode TG1 is positioned above the first active layer ACT1, but embodiments according to the present disclosure are not limited thereto. The first thin film transistor ST1 may be formed in a bottom gate type in which the first gate electrode TG1 is positioned below the first active layer ACT1 or a double gate type in which the first gate electrode TG1 is positioned both above and below the first active layer ACT1.

The light emitting element layer EML may be located on the second organic film 180. The light emitting element layer EML may include light emitting elements 170 and a bank 190. Each of the light emitting elements 170 may include a first light emitting electrode 171, a light emitting layer 172, and a second light emitting electrode 173.

The first light emitting electrode 171 may be formed on the second organic film 180. The first light emitting electrode 171 may be connected to the second anode connection electrode ANDE2 through a third anode contact hole ANCT3 penetrating through the second organic film 180 to expose the second anode connection electrode ANDE2.

The first light emitting electrode 171 may be formed on the second organic film 180. The first light emitting electrode 171 may be connected to the second anode connection electrode ANDE2 through a third anode contact hole ANCT3 penetrating through the second organic film 180 to expose the second anode connection electrode ANDE2.

In a top emission structure in which light is emitted toward the second light emitting electrode 173 based on the light emitting layer 172, the first light emitting electrode 171 may be formed of a metal material having high reflectance, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank 190 may be formed to partition the first light emitting electrode 171 on the second organic film 180 to define a light emitting area EA. The bank 190 may include an opening that exposes at least a portion of an upper surface of the first light emitting electrode 171. The bank 190 may be formed to cover an edge of the first light emitting electrode 171. The bank 190 may be formed of an organic film such as an acrylic resin, an epoxy resin, a phenolic resin, a polyamide resin, or a polyimide resin.

The light emitting area EA refers to an area in which the first light emitting electrode 171, the light emitting layer 172, and the second light emitting electrode 173 are sequentially stacked and holes from the first light emitting electrode 171 and electrons from the second light emitting electrode 173 are bonded to each other in the light emitting layer 172 to emit light. The light emitting area EA may be defined by the opening of the bank 190.

The light emitting layer 172 is formed on the first light emitting electrode 171 and the bank 190. The light emitting layer 172 may be located within the opening of the bank 190, but embodiments according to the present disclosure are not limited thereto. The light emitting layer 172 may include an organic material to emit light of a color (e.g., a set or predetermined color). For example, the light emitting layer 172 may include a hole transporting layer, an organic material layer, and an electron transporting layer.

The second light emitting electrode 173 may be located on the light emitting layer 172. The second light emitting electrode 173 may be formed to cover the light emitting layer 172. The second light emitting electrode 173 may be a common layer commonly formed in all the light emitting areas EA. According to some embodiments, a capping layer may be formed on the second light emitting electrode 173.

In the top emission structure, the second light emitting electrode 173 may be formed of transparent conductive oxide (TCO) such as indium tin oxide (ITO) or indium zinc oxide (IZO) capable of transmitting light, or a semi-transmissive conductive material such as magnesium (Mg), silver (Ag), or an alloy of magnesium (Mg) and silver (Ag). When the second light emitting electrode 173 is formed of the semi-transmissive conductive material, light emission efficiency may be increased by a micro cavity.

The thin film encapsulation layer TFEL may be located on the second light emitting electrode 173. The thin film encapsulation layer TFEL may include at least one inorganic film to prevent or reduce instances of contaminants such as oxygen or moisture permeating into the light emitting element layer. In addition, the thin film encapsulation layer TFEL may include at least one organic film to protect the light emitting element layer from foreign substances such as dust. For example, the thin film encapsulation layer TFEL may include a first encapsulation film TFE1, a second encapsulation film TFE2, and a third encapsulation film TFE3.

The first encapsulation film TFE1 (e.g., a first inorganic encapsulation film) may be located on the second light emitting electrode 173. The first encapsulation film TFE1 may be an inorganic film of a single layer or a multi-layer. The first encapsulation film TFE1 may be formed of a single film or a multi-film in which one or more inorganic films of a silicon nitride layer, a silicon oxynitride layer, a silicon oxide layer, a titanium oxide layer, and an aluminum oxide layer are alternately stacked.

The second encapsulation film TFE2 (e.g., a first organic encapsulation film) may be located on the first encapsulation film TFE1. The second encapsulation film TFE2 may be an organic film of a single layer or a multi-layer. The second encapsulation film TFE2 may include a polymer-based material. Examples of the polymer-based material may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, etc.), or any combination thereof.

The third encapsulation film TFE3 (e.g., a second inorganic encapsulation film) may be located on the second encapsulation film TFE2. The third encapsulation film TFE3 may be an inorganic film of a single layer or a multi-layer. The third encapsulation film TFE3 may include the same material as the first encapsulation film TFE1. For example, the third encapsulation film TFE3 may be formed of a single film or a multi-film in which one or more inorganic films of a silicon nitride layer, a silicon oxynitride layer, a silicon oxide layer, a titanium oxide layer, and an aluminum oxide layer are alternately stacked.

The touch sensor layer TSU may be located on the thin film encapsulation layer TFEL. The touch sensor layer TSU may include a plurality of touch electrodes for sensing a user's touch in a capacitance method, and touch lines connecting the plurality of touch electrodes and the touch driver. For example, the touch sensor layer TSU may sense the user's touch in a mutual capacitance method or a self-capacitance method.

According to some embodiments, the touch sensor layer TSU may be located on a separate substrate located on the display layer DU. In this case, the substrate supporting the touch sensor layer TSU may be an encapsulation member that encapsulates the display layer DU.

The plurality of touch electrodes of the touch sensor layer TSU may be located in a touch sensor area overlapping the display area. The touch lines of the touch sensor layer TSU may be located in a touch peripheral area overlapping the non-display area.

The touch sensor layer TSU may include a first touch insulating film SIL1, a first touch electrode REL, a second touch insulating film SIL2, a second touch electrode TEL, and a third touch insulating film SIL3.

The first touch insulating film SIL1 may be located on the thin film encapsulation layer TFEL. The first touch insulating film SIL1 may have insulation and optical functions. The first touch insulating film SIL1 may include at least one inorganic film. For example, the first touch insulating film SIL1 may be an inorganic film including at least one of a silicon nitride layer, a silicon oxynitride layer, a silicon oxide layer, a titanium oxide layer, or an aluminum oxide layer. According to some embodiments, the first touch insulating film SIL1 may be omitted.

The first touch electrode REL may be located on the first touch insulating film SIL1. The first touch electrode REL may not overlap the light emitting element 170. The first touch electrode REL may be formed as a single layer made of molybdenum (Mo), titanium (Ti), copper (Cu), aluminum (Al), or indium tin oxide (ITO), or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The second touch insulating film SIL2 may cover the first touch electrode REL and the first touch insulating film SIL1. The second touch insulating film SIL2 may have insulation and optical functions. For example, the second touch insulating film SIL2 may be made of the materials illustrated in the first touch insulating film SIL1.

The second touch electrode TEL may be located on the second touch insulating film SIL2. The second touch electrode TEL may not overlap the light emitting element 170. The second touch electrode TEL may be formed as a single layer made of molybdenum (Mo), titanium (Ti), copper (Cu), aluminum (Al), or indium tin oxide (ITO), or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The third touch insulating film SIL3 may cover the second touch electrode TEL and the second touch insulating film SIL2. The third touch insulating film SIL3 may have insulation and optical functions. The third touch insulating film SIL3 may be made of the materials illustrated in the second touch insulating film SIL2.

According to some embodiments, the first touch insulating film SIL1, the second touch insulating film SIL2, and the third touch insulating film SIL3 may be organic films. For example, the first touch insulating film SIL1, the second touch insulating film SIL2, and the third touch insulating film SIL3 may be organic films made of an acryl resin, an epoxy resin, a phenolic resin, a polyamide resin, a polyimide resin, or the like.

The touch sensor layer TSU may further include a planarization film PAS for planarization. The planarization film PAS may be formed of an organic film made of an acrylic resin, an epoxy resin, a phenolic resin, a polyamide resin, a polyimide resin, or the like.

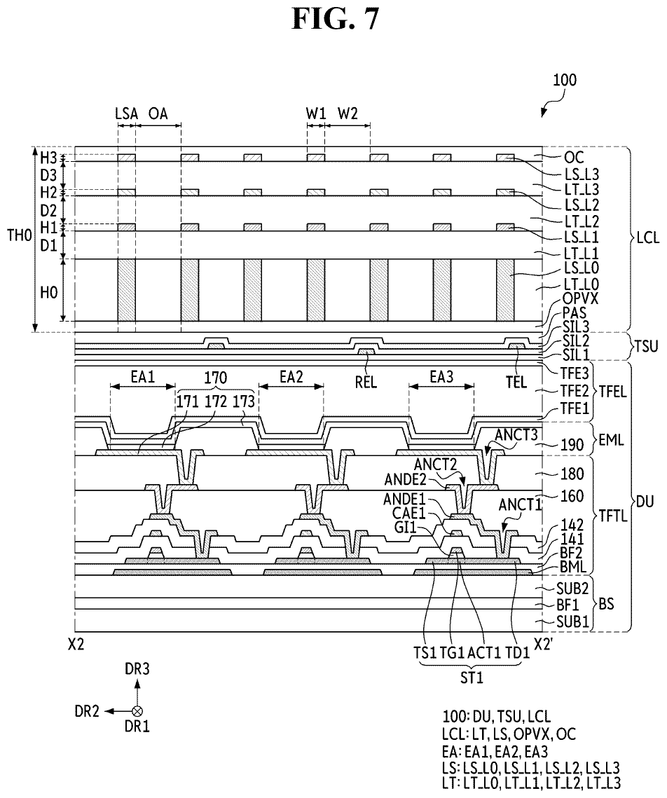

FIG. 6 is a plan view illustrating a portion of a display area according to some embodiments. FIG. 7 is a cross-sectional view taken along the line X2-X2′ of FIG. 6.

Referring to FIGS. 6 and 7 in addition to FIGS. 1 and 2, the display area DA of the display device 10 may include a plurality of light emitting areas EA. The light emitting area EA may be an area where light emitted by the light emitting element 170 emits. The light emitting area EA may be defined by the bank 190. For example, the plurality of light emitting areas EA may be areas that overlap the light emitting layer 172 located within the opening of the bank 190. The light emitting area EA may be an area where the first light emitting electrode 171, the light emitting layer 172, and the second light emitting electrode 173 are sequentially stacked while overlapping each other.

According to some embodiments, the plurality of light emitting areas EA may include a first light emitting area EA1, a second light emitting area EA2, and a third light emitting area EA3. It is illustrated in the drawing that three types of light emitting areas EA are included in the display area DA, but embodiments according to the present disclosure are not limited thereto and more or less than three types of light emitting areas EA may be included in the display area DA.

The first light emitting area EA1 may emit light of a first color, the second light emitting area EA2 may emit light of a second color, and the third light emitting area EA3 may emit light of a third color. The light of the first color may be light in a red wavelength band, the light of the second color may be light in a green wavelength band, and the light of the third color may be light in a blue wavelength band. The red wavelength band may be a wavelength band in a range of 600 nanometers (nm) to 750 nm (or approximately 600 nm to 750 nm), the green wavelength band may be a wavelength band in a range of 480 nm to 560 nm (or approximately 480 nm to 560 nm), and the blue wavelength band may be a wavelength band in a range of 370 nm to 460 nm (or approximately 370 nm to 460 nm), but embodiments according to the present disclosure are not limited thereto.

The first to third light emitting areas EA1, EA2, and EA3 may each have a rectangular, square, or diamond planar shape. For example, as illustrated in the drawing, the first to third light emitting areas EA1, EA2, and EA3 may have a rectangular shape with rounded corners, but embodiments according to the present disclosure are not limited thereto.

According to some embodiments, the areas of the first to third light emitting areas EA1, EA2, and EA3 may be the same. The first to third light emitting areas EA1, EA2, and EA3 may each extend in the first direction DR1 and may be arranged in parallel to each other along the second direction DR2.

According to some embodiments, the areas of the first to third light emitting areas EA1, EA2, and EA3 may be different. The first to third light emitting areas EA1, EA2, and EA3 may each extend in the second direction DR2 and may be arranged in parallel to each other along the first direction DR1.

FIG. 6 illustrates an example in which the transmissive area OA and the non-transmissive area LSA extend in the first direction DR1 as in the display device 10 according to the embodiments of FIG. 1.

The light emitting areas EA of the display area DA may overlap the transmissive area OA and the non-transmissive area LSA in the third direction DR3. For example, the first to third light emitting areas EA1, EA2, and EA3 may overlap the transmissive area OA and the non-transmissive area LSA in the third direction DR3.

The transmissive area OA may be an area where the light blocking film LS of the light control layer LCL is not located. The non-transmissive area LSA may be an area where the light blocking film LS of the light control layer LCL is located.

The light control layer LCL may be located on the display layer DU or the touch sensor layer TSU. The light control layer LCL may control a viewing angle of light emitted from the light emitting layer 172. For example, when light emitted from the light emitting layer 172 travels at an angle (e.g., a set or predetermined angle) or less with respect to the third direction DR3, the light may be emitted to the outside. On the other hand, when the light emitted from the light emitting layer 172 travels beyond an angle (e.g., a set or predetermined angle) with respect to the third direction DR3, the light may be absorbed or blocked by the light blocking film LS and not emitted to the outside.

The light control layer LCL may include a light transmissive lower film OPVX, a light transmissive film LT, a light blocking film LS, and an overcoat layer OC.

The light transmissive lower film OPVX may be located on the display layer DU or the touch sensor layer TSU. The light transmissive lower film OPVX may transmit the light emitted from the light emitting layer 172. The light transmissive lower film OPVX may include a transparent organic material. For example, the light transmissive lower film OPVX may include an organic film made of an acryl resin, an epoxy resin, a phenolic resin, a polyamide resin, a polyimide resin, or the like.

The light transmissive lower film OPVX may be located below the light transmissive film LT to prevent or reduce overflow of the material of the light transmissive film LT during an inkjet printing process for forming the light transmissive film LT. For example, the material of the light transmissive film LT may be applied in the form of ink on the light transmissive lower film OPVX, and the overflow of the material of the light transmissive film LT may be prevented or reduced due to a contact angle of the ink and a surface tension of the ink on the light transmissive lower film OPVX.

In addition, the light transmissive lower film OPVX may prevent or reduce damage to the layer positioned below the light control layer LCL due to over-etching when a portion of the light transmissive film LT is dry etched to form the light blocking film LS.

The light transmissive film LT and the light blocking film LS may be located on the light transmissive lower film OPVX.

The light transmissive film LT may transmit the light emitted from the light emitting layer 172. The light transmissive film LT may include a transparent organic material. For example, the light transmissive film LT may include an organic film made of an acryl resin, an epoxy resin, a phenolic resin, a polyamide resin, a polyimide resin, or the like.

The light transmissive film LT may be located in the transmissive area OA. As illustrated in FIG. 6, the light transmissive film LT may be arranged alternately with the light blocking films LS in the first direction DR1 or the second direction DR2.

The light blocking film LS may absorb or block the light emitted from the light emitting layer 172. The light blocking film LS may include a light blocking organic material. For example, the light blocking film LS may include an organic material including an organic black pigment such as carbon black, as a photosensitive resin capable of absorbing or blocking light.

The light blocking film LS may be located in the non-transmissive area LSA. As illustrated in FIG. 6, the light blocking film LS may be arranged alternately with the light transmissive film LT in the first direction DR1 or the second direction DR2.

According to some embodiments, the light transmissive layer LT may include a louver support layer LT_L0, a first transmissive layer LT_L1, a second transmissive layer LT_L2, and a third transmissive layer LT_L3. The light blocking film LS may include a louver layer LS_L0, a first light blocking layer LS_L1, a second light blocking layer LS_L2, and a third light blocking layer LS_L3.

The louver support layer LT_L0 of the light transmissive film LT and the louver layer LS_L0 of the light blocking film LS may be located on the light transmissive lower film OPVX. The first transmissive layer LT_L1 may be located on the louver support layer LT_L0 and the louver layer LS_L0. The first light blocking layer LS_L1 may be located on the first transmissive layer LT_L1. The second transmissive layer LT_L2 may be located on the first light blocking layer LS_L1 and the first transmissive layer LT_L1. The second light blocking layer LS_L2 may be located on the second transmissive layer LT_L2. The third transmissive layer LT_L3 may be located on the second light blocking layer LS_L2 and the second transmissive layer LT_L2. The third light blocking layer LS_L3 may be located on the third transmissive layer LT_L3.

The louver support layer LT_L0 and the louver layer LS_L0 may be arranged to alternate with each other in the horizontal direction (e.g., in the first direction DR1 or the second direction DR2). According to some embodiments, a height H0 of the louver layer LS_L0 in the third direction DR3 may be equal (or substantially equal) to a height of the louver support layer LT_L0 in the third direction DR3.

The louver layer LS_L0, the first light blocking layer LS_L1, the second light blocking layer LS_L2, and the third light blocking layer LS_L3 may each include a plurality of light blocking patterns spaced apart from each other in the first direction DR1 or the second direction DR2. For example, as illustrated in FIG. 6, when the light blocking films LS are arranged to be spaced apart from each other in the second direction DR2, the plurality of light blocking patterns of each of the louver layer LS_L0, the first light blocking layer LS_L1, the second light blocking layer LS_L2, and the third light blocking layer LS_L3 may be spaced apart from each other in the second direction DR2.

The plurality of light blocking patterns of each of the louver layer LS_L0, the first light blocking layer LS_L1, the second light blocking layer LS_L2, and the third light blocking layer LS_L3 may overlap each other in the third direction DR3. For example, the plurality of light blocking patterns of each of the louver layer LS_L0, the first light blocking layer LS_L1, the second light blocking layer LS_L2, and the third light blocking layer LS_L3 may corresponding to each other in a one-to-one manner in the third direction DR3.

According to some embodiments, widths of the plurality of light blocking patterns of each of the louver layer LS_L0, the first light blocking layer LS_L1, the second light blocking layer LS_L2, and the third light blocking layer LS_L3 may be the same (or substantially the same), but embodiments according to the present disclosure are not limited thereto. According to some embodiments, the widths of the plurality of light blocking patterns of each of the louver layer LS_L0, the first light blocking layer LS_L1, the second light blocking layer LS_L2, and the third light blocking layer LS_L3 may be different from each other.

According to some embodiments, the louver support layer LT_L0 may include a different material from the first transmissive layer LT_L1, the second transmissive layer LT_L2, and the third transmissive layer LT_L3 and may be formed by a different process therefrom.

For example, the louver support layer LT_L0 may include at least one of an ester-based compound or a phosphine oxide compound. For example, the number of carbon atoms of the ester-based compound may be 30 or less. In addition, the louver support layer LT_L0 may be formed by an inkjet printing process and a dry etching process.

On the other hand, the first transmissive layer LT_L1, the second transmissive layer LT_L2, and the third transmissive layer LT_L3 may include at least one of propylene glycol methyl ether acetate, methacrylic acid-benzylmethacrylic acid copolymer, multi-functional acrylate, or a photo initiator. In addition, the first transmissive layer LT_L1, the second transmissive layer LT_L2, and the third transmissive layer LT_L3 may be formed by a deposition process and a patterning process such as photolithography.

According to some embodiments, the louver support layer LT_L0 may include a different material from the first light blocking layer LS_L1, the second light blocking layer LS_L2, and the third light blocking layer LS_L3 and may be formed by a different process therefrom.

For example, the louver layer LS_L0 may be formed by a coating process such as screen printing, scribing, etc., and a polishing process (chemical-mechanical polishing (CMP) process). The louver layer LS_L0 may include at least one of an acrylate-based compound, an isocyanate-based compound, a polyamine-based compound such as polyethylene polyamine (PEPA), or polypropylene polyamine (PPPA), or an amide-based compound such as ethylenediamine, diethylenetriamine, and diethyltoluenediamine, as a curing agent to ensure that the remaining materials are well bonded to each other after an ink solvent is volatilized during the coating process.

On the other hand, the first light blocking layer LS_L1, the second light blocking layer LS_L2, and the third light blocking layer LS_L3 may include at least one of propylene glycol methyl ether acetate, methacrylic acid-benzylmethacrylic acid copolymer, multi-functional acrylate, or a photo initiator. The first light blocking layer LS_L1, the second light blocking layer LS_L2, and the third light blocking layer LS_L3 may be formed by a deposition process and a patterning process such as photolithography.

The overcoat layer OC may be located on the third light blocking layer LS_L3 and the third transmissive layer LT_L3. The overcoat layer OC may include an organic film made of an acryl resin, an epoxy resin, a phenolic resin, a polyamide resin, a polyimide resin, or the like.

Meanwhile, according to some embodiments, like the first transmissive layer LT_L1, the second transmissive layer LT_L2, and the third transmissive layer LT_L3, the light transmissive lower film OPVX and the overcoat layer OC may include at least one of propylene glycol methyl ether acetate, methacrylic acid-benzylmethacrylic acid copolymer, multi-functional acrylate, or a photo initiator. Like the first transmissive layer LT_L1, the second transmissive layer LT_L2, and the third transmissive layer LT_L3, the light transmissive lower film OPVX and the overcoat layer OC may be formed by a deposition process and a patterning process such as photolithography.

The height H0 of the louver layer LS_L0 may be greater than a height H1 of the first light blocking layer LS_L1, a height H2 of the second light blocking layer LS_L2, and a height H3 of the third light blocking layer LS_L3. For example, the height H0 of the louver layer LS_L0 may be 3 to 30 (or approximately 3 to 30) times the height H1 of the first light blocking layer LS_L1, the height H2 of the second light blocking layer LS_L2, and the height H3 of the third light blocking layer LS_L3. The height H0 of the louver layer LS_L0, the height H1 of the first light blocking layer LS_L1, the height H2 of the second light blocking layer LS_L2, and the height H3 of the third light blocking layer LS_L3 each mean a length in the third direction DR3.

According to some embodiments, the height H1 of the first light blocking layer LS_L1, the height H2 of the second light blocking layer LS_L2, and the height H3 of the third light blocking layer LS_L3 may each be in a range of 1 micrometer (μm) to 5 μm (or approximately 1 μm to 5 μm). Preferably, the height H1 of the first light blocking layer LS_L1, the height H2 of the second light blocking layer LS_L2, and the height H3 of the third light blocking layer LS_L3 may each be in a range of 1.5 μm to 2 μm (or approximately 1.5 μm to 2 μm).

According to some embodiments, the height H0 of the louver layer LS_L0 may be 30 μm (or approximately 30 μm) or less. Preferably, the height H0 of the louver layer LS_L0 may be in a range of 15 μm to 30 μm (or approximately 15 μm to 30 μm).

It is illustrated in the drawing that the height H1 of the first light blocking layer LS_L1, the height H2 of the second light blocking layer LS_L2, and the height H3 of the third light blocking layer LS_L3 are the same as each other, but the present disclosure is not limited thereto. The height H1 of the first light blocking layer LS_L1, the height H2 of the second light blocking layer LS_L2, and the height H3 of the third light blocking layer LS_L3 may be different from each other.

A first distance D1, which is a distance in the third direction DR3 between the louver layer LS_L0 and the first light blocking layer LS_L1, a second distance D2, which is a distance in the third direction DR3 between the first light blocking layer LS_L1 and the second light blocking layer LS_L2, and a third distance D3, which is a distance in the third direction DR3 between the second light blocking layer LS_L2 and the third light blocking layer LS_L3 may be each 5 μm to 20 μm. Preferably, the first distance D1, the second distance D2, and the third distance D3 may each be 10 μm (or approximately 10 μm).

According to some embodiments, a total height TH0 of the light control layer LCL may be 40 μm (or approximately 40 μm) or more. Preferably, the total height TH0 of the light control layer LCL may be 50 μm (or approximately 50 μm) or more. The total height TH0 of the light control layer LCL refers to the length of the light control layer LCL in the third direction DR3.

A width W1 of the non-transmissive area LSA may be smaller than a width W2 of the transmissive area OA. According to some embodiments, the width W1 of the non-transmissive area LSA may be in a range of 7 μm to 12 μm (or approximately 7 μm to 12 μm), and the width W2 of the transmissive area OA may be in a range of 10 μm to 30 μm (or approximately 10 μm to 30 μm), but embodiments according to the present disclosure are not limited thereto.

The display device 10 according to some embodiments may relatively improve reliability of the light control layer LCL by arranging a multi-stage light blocking layer (multi black matrix) on the louver layer LS_L0 having a height (e.g., a set or predetermined height).

For example, as the total height TH0 of the light control layer LCL is high and an aspect ratio of the light blocking pattern included in the louver layer LS_L0 increases, viewing angle control characteristics of the light control layer LCL may be relatively improved. Here, the aspect ratio of the light blocking pattern included in the louver layer LS_L0 refers to a ratio of a height of the light blocking pattern in the vertical direction (e.g., the third direction DR3) to a width thereof in the horizontal direction (e.g., the first and second directions DR1 and DR2).

The louver support layer LT_L0 may be formed by being entirely applied onto the light transmissive lower film OPVX through an inkjet printing process and then dry etching a portion where the louver layer LS_L0 is to be located. The louver layer LS_L0 may be formed by filling the etched portion of the louver support layer LT_L0. Therefore, the aspect ratio of the light blocking pattern included in the louver layer LS_L0 is determined according to an aspect ratio of the etched portion of the louver support layer LT_L0.

However, when the height of the louver support layer LT_L0 exceeds a certain level (e.g., 30 μm), a side profile of the etched portion where the louver layer LS_L0 will be arranged may not be vertically formed but may be formed in a reverse-tapered shape. As a result, the aspect ratio of the light blocking pattern included in the louver layer LS_L0 becomes small, which may weaken the viewing angle control characteristics of the light control layer LCL or cause a light leakage phenomenon.

On the other hand, the display device 10 according to some embodiments may relatively improve the side profile characteristics of the louver layer LS_L0 by relatively reducing the height of the louver layer LS_L0, and may simultaneously relatively improve the viewing angle control characteristics by arranging the first light blocking layer LS_L1, the second light blocking layer LS_L2, and the third light blocking layer LS_L3 on the louver layer LS_L0.

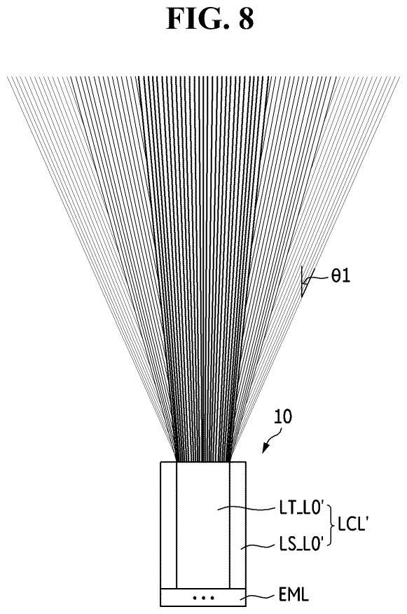

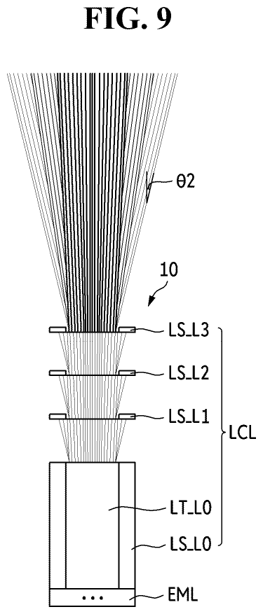

Hereinafter, a method in which the viewing angle control characteristics are relatively improved by arranging the first light blocking layer LS_L1, the second light blocking layer LS_L2, and the third light blocking layer LS_L3 on the louver layer LS_L0 will be described with reference to FIGS. 8 and 9.

FIG. 8 is a schematic view illustrating a viewing angle of a display device according to a comparative example. FIG. 9 is a schematic view illustrating a viewing angle of the display device according to the embodiments of FIG. 7.

Referring to FIGS. 8 and 9 in addition to FIG. 7, a light control layer LCL′ of the display device 10 according to the comparative example may include a louver layer LS_L0′ and a louver support layer LT_L0′. The light control layer LCL of the display device 10 according to some embodiments may include a louver layer LS_L0, a louver support layer LT_L0, a first light blocking layer LS_L1, a second light blocking layer LS_L2, and a third light blocking layer LS_L3.

A viewing angle θ1 of the light control layer LCL′ according to the comparative example that does not include the first light blocking layer LS_L1, the second light blocking layer LS_L2, and the third light blocking layer LS_L3 may be greater than a viewing angle θ2 of the light control layer LCL according to some embodiments that includes the first light blocking layer LS_L1, the second light blocking layer LS_L2, and the third light blocking layer LS_L3. For example, the viewing angle θ2 of the light control layer LCL according to some embodiments may be 15 degrees (or approximately 15 degrees) or less.

As such, the light control layer LCL of the display device 10 according to some embodiments may relatively improve the side profile characteristics of the louver layer LS_L0 by relatively reducing the height of the louver layer LS_L0, and may simultaneously relatively improve the viewing angle control characteristics by arranging the first light blocking layer LS_L1, the second light blocking layer LS_L2, and the third light blocking layer LS_L3 on the louver layer LS_L0.

Hereinafter, other characteristics of the display device according to some embodiments will be described. In the following embodiments, the same components as those of the above-described embodiments will be denoted by the same reference numerals, and some overlapping description thereof may be omitted or simplified and differences will be mainly described.

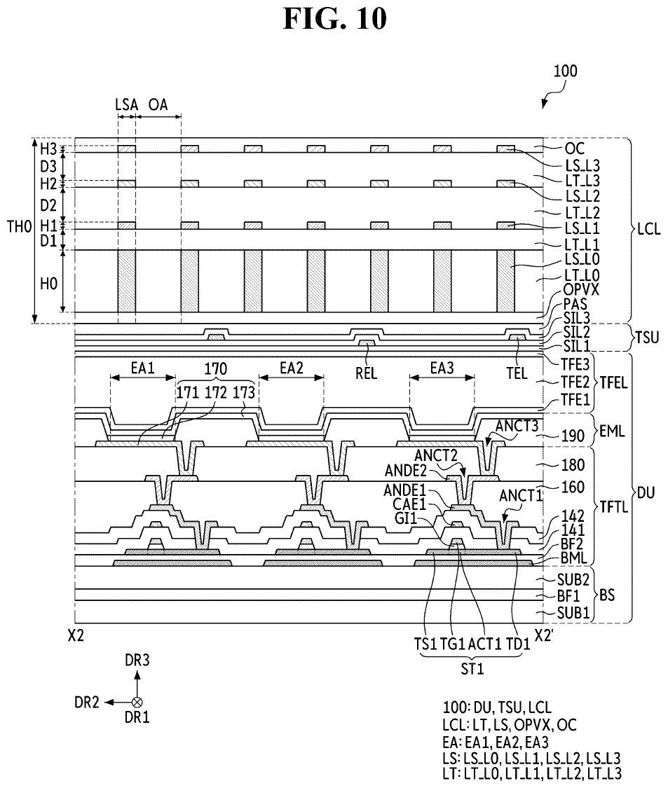

FIG. 10 is a cross-sectional view illustrating a display panel according to some embodiments.

Referring to FIG. 10, a display device 10 according to some embodiments is different from the display device 10 according to the embodiments described with reference to FIG. 7 and the like in that the first to third distances D1, D2, and D3 are different.

For example, in the display device 10 according to some embodiments, the first to third distances D1, D2, and D3 may be different from each other. For example, as illustrated in the drawing, the first distance D1 may be smaller than the third distance D3, and the third distance D3 may be smaller than the second distance D2.

According to some embodiments, the first distance D1 may be smaller than the second distance D2, and the second distance D2 may be smaller than the third distance D3. According to some embodiments, the second distance D2 may be smaller than the first distance D1, and the first distance D1 may be smaller than the third distance D3. According to some embodiments, the second distance D2 may be smaller than the third distance D3, and the third distance D3 may be smaller than the first distance D1. According to some embodiments, the third distance D3 may be smaller than the first distance D1, and the first distance D1 may be smaller than the second distance D2. According to some embodiments, the third distance D3 may be smaller than the second distance D2, and the second distance D2 may be smaller than the first distance D1.

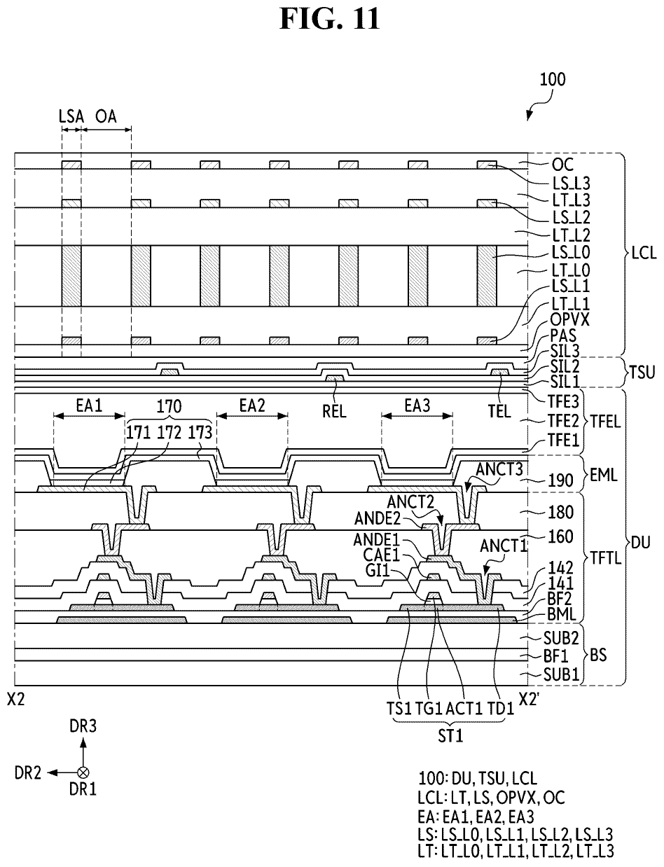

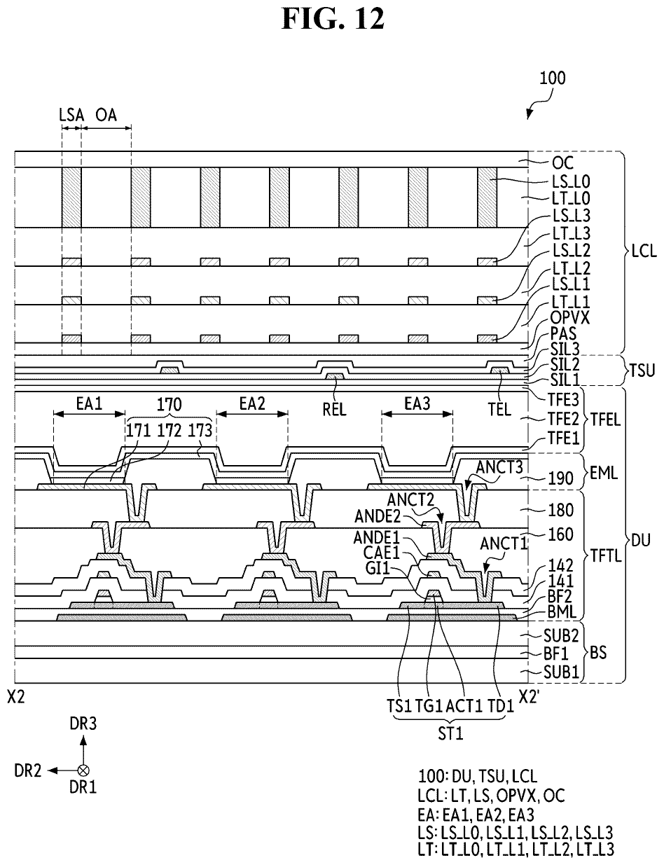

FIG. 11 is a cross-sectional view illustrating a display panel according to some embodiments. FIG. 12 is a cross-sectional view illustrating a display panel according to some embodiments.

Referring to FIGS. 11 and 12, the display device 10 according to some embodiments is different from the display device 10 according to the embodiments described with reference to FIG. 7 and the like in that a detailed stacking order of the light control layer LCL is different.

For example, as illustrated in FIG. 11, the first light blocking layer LS_L1 may be located on the light transmissive lower film OPVX. The first transmissive layer LT_L1 may be located on the first light blocking layer LS_L1 and the light transmissive lower film OPVX. The louver layer LS_L0 may be located on the first transmissive layer LT_L1. The louver support layer LT_L0 may be located on the first transmissive layer LT_L1. The louver layer LS_L0 and the louver support layer LT_L0 may be arranged alternately with each other on the first transmissive layer LT_L1. The second transmissive layer LT_L2 may be located on the louver layer LS_L0 and the louver support layer LT_L0. The second light blocking layer LS_L2 may be located on the second transmissive layer LT_L2. The third transmissive layer LT_L3 may be located on the second light blocking layer LS_L2 and the second transmissive layer LT_L2. The third light blocking layer LS_L3 may be located on the third transmissive layer LT_L3. The overcoat layer OC may be located on the third light blocking layer LS_L3 and the third transmissive layer LT_L3.

According to some embodiments, as illustrated in FIG. 12, the first light blocking layer LS_L1 may be located on the light transmissive lower film OPVX. The first transmissive layer LT_L1 may be located on the first light blocking layer LS_L1 and the light transmissive lower film OPVX. The second light blocking layer LS_L2 may be located on the first transmissive layer LT_L1. The second transmissive layer LT_L2 may be located on the second light blocking layer LS_L2 and the first transmissive layer LT_L1. The third light blocking layer LS_L3 may be located on the second transmissive layer LT_L2. The third transmissive layer LT_L3 may be located on the third light blocking layer LS_L3 and the second transmissive layer LT_L2. The louver layer LS_L0 may be located on the third transmissive layer LT_L3. The louver support layer LT_L0 may be located on the third transmissive layer LT_L3. The louver layer LS_L0 and the louver support layer LT_L0 may be arranged alternately with each other on the third transmissive layer LT_L3. The overcoat layer OC may be located on the louver layer LS_L0 and the louver support layer LT_L0.

In addition, according to some embodiments, the louver layer LS_L0 may be located between the second light blocking layer LS_L2 and the third light blocking layer LS_L3. In this case, the louver support layer LT_L0 may be located between the second transmissive layer LT_L2 and the third transmissive layer LT_L3.

Meanwhile, according to some embodiments, the light transmissive lower film OPVX may be located directly below the louver layer LS_L0 and the louver support layer LT_L0 instead of being located directly below the first light blocking layer LS_L1.

For example, in the embodiments of FIG. 11, the light transmissive lower film OPVX may also be positioned between the first transmissive layer LT_L1 and the louver support layer LT_L0 and between the first transmissive layer LT_L1 and the louver layer LS_L0. In this case, the first light blocking layer LS_L1 may be located on the planarization film PAS of the touch sensor layer TSU.

As still another example, in the embodiments of FIG. 12, the light transmissive lower film OPVX may also be positioned between the third transmissive layer LT_L3 and the louver support layer LT_L0 and between the third transmissive layer LT_L3 and the louver layer LS_L0.

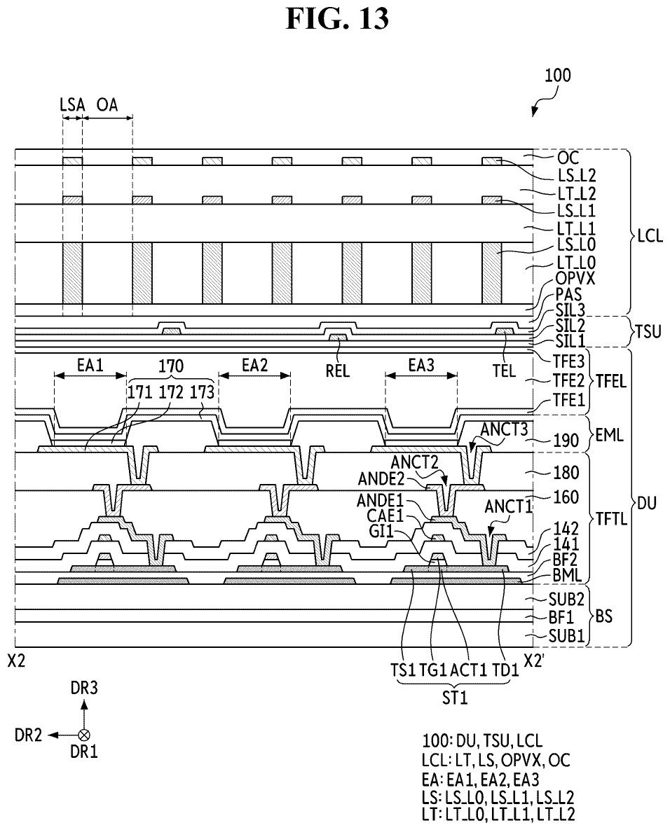

FIG. 13 is a cross-sectional view illustrating a display panel according to some embodiments.

Referring to FIG. 13, the display device 10 according to the present embodiments is different from the display device 10 according to the embodiments described with reference to FIG. 7 and the like in that the number of light blocking layers and transmissive layers is different.

For example, as illustrated in FIG. 13, the light control layer LCL may include two light blocking layers and two transmissive layers.

For example, the light transmissive film LT may include a first transmissive layer LT_L1 and a second transmissive layer LT_L2, and the light blocking film LS may include a first light blocking layer LS_L1 and a second light blocking layer LS_L2.

The first transmissive layer LT_L1 may be located on the louver layer LS_L0 and the louver support layer LT_L0. The first light blocking layer LS_L1 may be located on the first transmissive layer LT_L1. The second transmissive layer LT_L2 may be located on the first light blocking layer LS_L1 and the first transmissive layer LT_L1. The second light blocking layer LS_L2 may be located on the second transmissive layer LT_L2. The overcoat layer OC may be located on the second light blocking layer LS_L2 and the second transmissive layer LT_L2.

In addition, according to some embodiments, the light control layer LCL may include four or more light blocking layers and four or more transmissive layers.

The light control layer LCL according to some embodiments may relatively improve side profile characteristics of the louver layer LS_L0 and simultaneously relatively improve viewing angle control characteristics of the light control layer LCL by including at least two or more light blocking layers and transmissive layers.

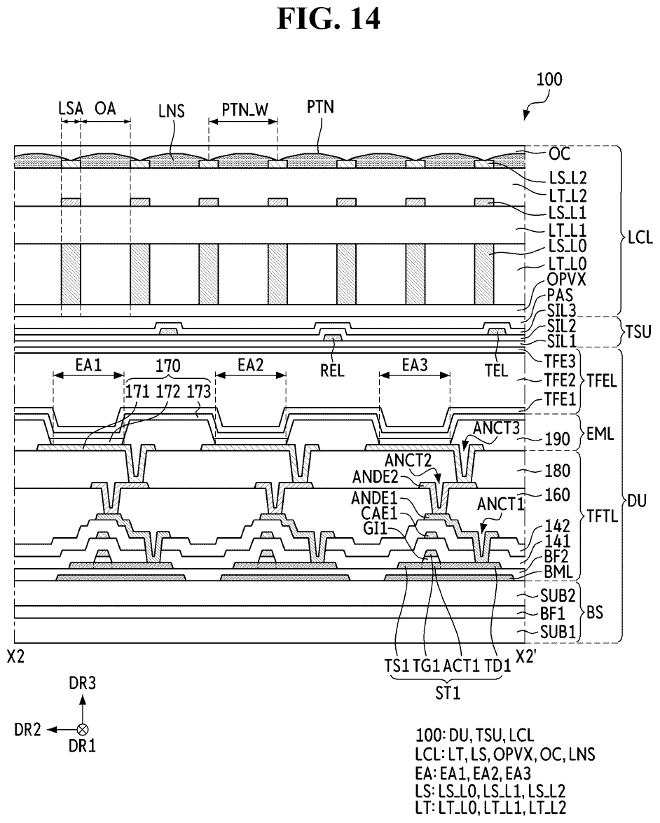

FIG. 14 is a cross-sectional view illustrating a display panel according to some embodiments.

Referring to FIG. 14, the display device 10 according to the present embodiments is different from the display device 10 according to the embodiments described with reference to FIG. 7 and the like in that it further includes an optical layer LNS.

For example, the light control layer LCL according to some embodiments may further include an optical layer or lense LNS. For convenience of explanation, FIG. 14 illustrates a case where there are two light blocking layers and two transmissive layers as an example, as in the display device 10 according to some embodiments as described with reference to FIG. 13, but embodiments according to the present disclosure are not limited thereto.

According to some embodiments, the optical layer LNS may be located on the second light blocking layer LS_L2 and the second transmissive layer LT_L2. However, the optical layer LNS is not limited thereto, and may also be located on the first light blocking layer LS_L1 and the first transmissive layer LT_L1.

The optical layer LNS may include a plurality of optical patterns PTN. Each of the plurality of optical patterns PTN may be located between the plurality of light blocking patterns of the second light blocking layer LS_L2.

Each of the plurality of optical patterns PTN may overlap the transmissive area OA in the third direction DR3. Each of the plurality of optical patterns PTN may be located in the transmissive area OA. For example, each of the plurality of optical patterns PTN may correspond to the transmissive area OA in a one-to-one manner.

As illustrated in the drawing, at least a portion of each of the plurality of optical patterns PTN may overlap the non-transmissive area LSA or the plurality of light blocking patterns in the third direction DR3. In this case, a width PTN_W of each of the plurality of optical patterns PTN may be greater than the width of the transmissive area OA.

However, the plurality of optical patterns PTN are not limited thereto, and may not overlap the non-transmissive area LSA and the plurality of light blocking patterns in the third direction DR3. In this case, the plurality of optical patterns PTN may be arranged to be spaced apart from each other. In addition, the width PTN_W of each of the plurality of optical patterns PTN may be equal to or smaller than the width of the transmissive area OA.

The plurality of optical patterns PTN of the optical layer LNS may include a converging lens. For example, the plurality of optical patterns PTN of the optical layer LNS may include a convex lens that is convex toward a display surface. The display surface is a surface opposite to the surface on which the light emitting layer 172 is located based on the optical layer LNS and refers to a surface adjacent to the overcoat layer OC. According to some embodiments, the plurality of optical patterns PTN of the optical layer LNS may include at least one of a lenticular lens array or a micro lens array.

According to some embodiments, a refractive index of the optical layer LNS may be greater than a refractive index of the light blocking film LS and the light transmissive film LT. For example, the refractive index of the optical layer LNS may be 1.6 (or approximately 1.6) or more, and the refractive index of the light blocking film LS and the light transmissive film LT may be 1.5 (or approximately 1.5) or less. In the present specification, the refractive index refers to an absolute refractive index of sodium (Na) to a D-line (λ=589 nm, yellow), and may be, for example, an absolute refractive index measured based on a wavelength of 589 nm, for example according to the Cauchy Film Model, using a refractive index meter (e.g., Ellipsometer (Ellipsometer M-2000, J. A. Woollam)) at 25° C. and under 50% relative humidity.

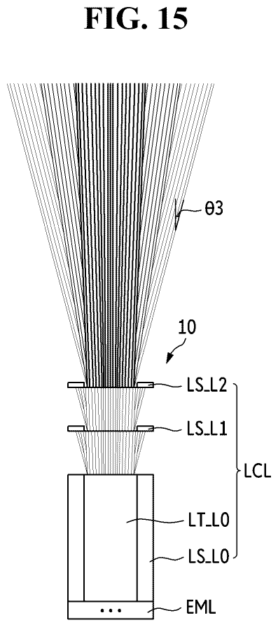

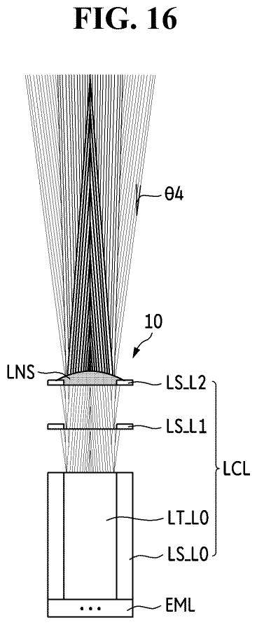

Hereinafter, the viewing angle control characteristics of the light control layer including the converging lens will be described with reference to FIGS. 15 and 16.

FIG. 15 is a schematic view illustrating a viewing angle of a display device according to embodiments illustrated and described with respect to FIG. 13. FIG. 16 is a schematic view illustrating a viewing angle of a display device according to some embodiments as illustrated and described with respect to FIG. 14.

Referring to FIGS. 15 and 16 in addition to FIGS. 13 and 14, the display device 10 according to some embodiments as illustrated and described with respect to FIG. 15 may include the same light control layer LCL as the display device 10 according to some embodiments as illustrated and described with reference to FIG. 13. The display device 10 according to some embodiments as illustrated and described with respect to FIG. 16 may include the same light control layer LCL as the display device 10 according to some embodiments as illustrated and described with reference to FIG. 14. That is, the display device 10 according to the embodiments of FIGS. 15 and 16 each includes two light blocking layers, the display device 10 according to the embodiments of FIG. 15 may not include the optical layer LSN, and the display device 10 according to the embodiments of FIG. 16 may include the optical layer LSN.

A viewing angle θ3 of the display device 10 according to the embodiments of FIG. 15 that does not include the optical layer LSN may be greater than a viewing angle θ4 of the display device 10 according to the embodiments of FIG. 16 that includes the optical layer LSN. For example, the viewing angle θ3 of the display device 10 according to the embodiments of FIG. 15 may be 15 degrees (or approximately 15 degrees), and the viewing angle θ4 of the display device 10 according to the embodiments of FIG. 16 may be 7 degrees (or approximately 7 degrees).

In this way, as the light control layer LCL includes the optical layer LSN, the viewing angle control characteristics may be further relatively improved. Accordingly, the display device 10 according to the embodiments of FIGS. 14 and 16 may also include only one light blocking layer and one transmissive layer other than those illustrated in the drawings. That is, when the light control layer LCL includes the optical layer LSN, the light control layer LCL may include at least one or more light blocking layers and transmissive layers. Accordingly, a manufacturing process may be further simplified.

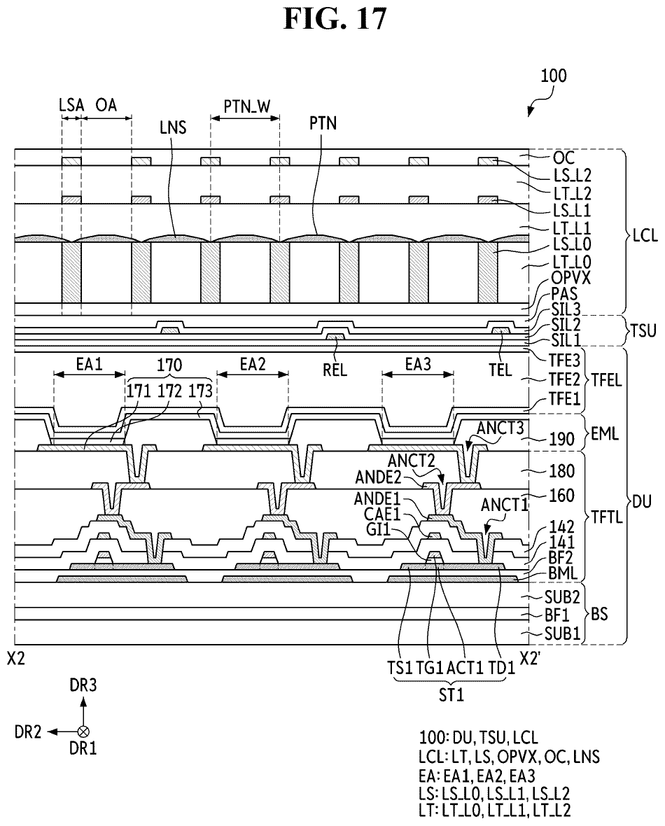

FIG. 17 is a cross-sectional view illustrating a display panel according to some embodiments.

Referring to FIG. 17, the display device 10 according to some embodiments is different from the display device 10 according to the embodiments described with reference to FIG. 14 and the like in that a position of the optical layer LNS is different.

For example, in the display device 10 according to some embodiments, the optical layer LSN may be located on the louver layer LS_L0 and the louver support layer LT_L0. The optical layer LSN may be located between the louver layer LS_L0 and the first transmissive layer LT_L1 and between the louver support layer LT_L0 and the first transmissive layer LT_L1.

Like the display device 10 according to some embodiments as described with reference to FIG. 14 and the like, the optical layer LSN may also be located on the louver layer LS_L0 and the louver support layer LT_L0 instead of being located on the first light blocking layer LS_L1 or the second light blocking layer LS_L2.

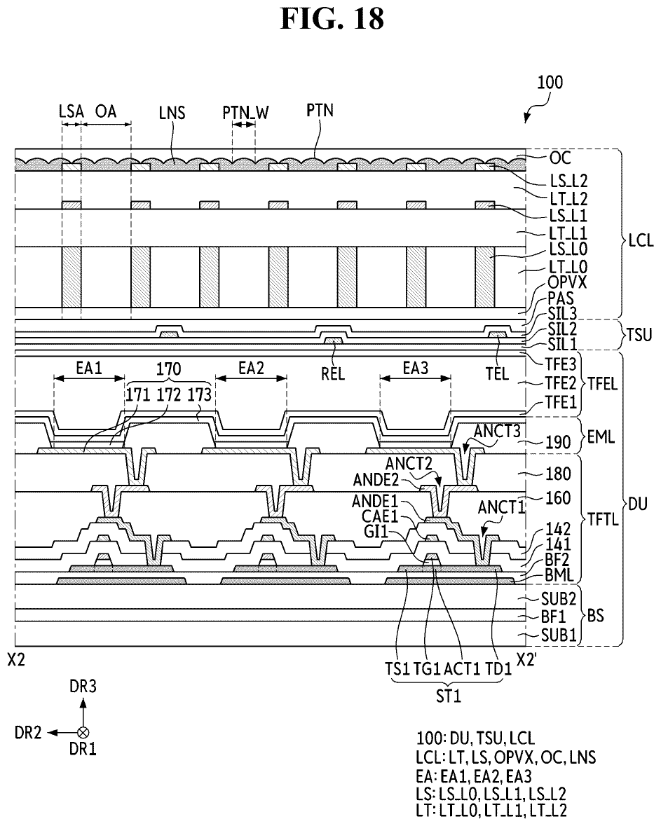

FIG. 18 is a cross-sectional view illustrating a display panel according to some embodiments.

Referring to FIG. 18, the display device 10 according to the present embodiments is different from the display device 10 according to the embodiments described with reference to FIGS. 14 and 17 the like in that a width of the plurality of optical patterns PTN of the optical layer LNS is different.

For example, the width PTN_W of the plurality of optical patterns PTN of the optical layer LSN may be smaller than the width of the transmissive area OA. The width PTN_W of the plurality of optical patterns PTN may be smaller than a distance between the plurality of light blocking patterns of the first light blocking layer LS_L1 or the second light blocking layer LS_L2.

There may be a plurality of optical patterns PTN overlapping one transmissive area OA in the third direction DR3. That is, the plurality of optical patterns PTN may be located between two light blocking patterns. For example, as illustrated in the drawing, one transmissive area OA may overlap three optical patterns PTN in the third direction DR3. That is, three optical patterns PTN may be located between the two light blocking patterns. However, the number of optical patterns PTN overlapping one transmissive area OA in the third direction DR3, that is, the number of optical patterns PTN located between the two light blocking patterns, is not limited thereto. As in the embodiments described above with reference to FIG. 14 and the like, one optical pattern PTN may also overlap one transmissive area OA in the third direction DR3, and two or more arbitrary numbers of optical patterns PTN may also overlap one transmissive area OA in the third direction DR3.

In concluding the detailed description, those skilled in the art will appreciate that many variations and modifications can be made to the disclosed embodiments without departing from the spirit and scope of embodiments according to the present disclosure. Therefore, the disclosed embodiments of the invention are used in a generic and descriptive sense only and not for purposes of limitation.

What is claimed is:

1. A display device comprising:
a substrate;
a light emitting element layer on the substrate and including a plurality of light emitting elements; and
a light control layer on the light emitting element layer,
wherein the light control layer includes:
a louver layer and a louver support layer on the light emitting element layer and arranged alternately with each other;
a first transmissive layer on the louver layer and the louver support layer;
a first light blocking layer on the first transmissive layer and including a plurality of light blocking patterns spaced apart from each other;
a second transmissive layer on the first transmissive layer and the first light blocking layer; and
a second light blocking layer on the second transmissive layer and including a plurality of light blocking patterns spaced apart from each other, and
wherein a height of the louver layer is greater than a height of the first light blocking layer and a height of the second light blocking layer.

2. The display device of claim 1, wherein the louver layer overlaps the plurality of light blocking patterns of the first light blocking layer and the plurality of light blocking patterns of the second light blocking layer.

3. The display device of claim 1, wherein the height of the louver layer is in a range of 3 to 30 times the height of the first light blocking layer and the height of the second light blocking layer, respectively.

4. The display device of claim 3, wherein the height of the louver layer is 30 micrometers (μm) or less.

5. The display device of claim 4, wherein the height of the first light blocking layer and the height of the second light blocking layer are each in a range of 1 μm to 5 μm.

6. The display device of claim 1, wherein a height of the light control layer is 40 micrometers (μm) or more.

7. The display device of claim 1, wherein a width of the plurality of light blocking patterns of the first light blocking layer is smaller than a distance between the plurality of light blocking patterns of the first light blocking layer.

8. The display device of claim 7, wherein the width of the plurality of light blocking patterns of the first light blocking layer is in a range of 7 micrometers (μm) to 12 μm, and
wherein the distance between the plurality of light blocking patterns of the first light blocking layer is in a range of 10 μm to 30 μm.

9. The display device of claim 1, wherein the louver layer includes a material different from the first light blocking layer and the second light blocking layer.

10. The display device of claim 9, wherein the louver layer includes at least one of an acrylate-based compound, an isocyanate-based compound, a polyamine-based compound such as polyethylene polyamine (PEPA) or polypropylene polyamine (PPPA), or an amide-based compound such as ethylenediamine, diethylenetriamine, or diethyltoluenediamine, and
wherein the first light blocking layer and the second light blocking layer include at least one of propylene glycol methyl ether acetate, methacrylic acid-benzylmethacrylic acid copolymer, multi-functional acrylate, or a photo initiator.

11. The display device of claim 10, wherein the louver layer is formed by a coating process and a polishing process, and
the first light blocking layer and the second light blocking layer are formed by a deposition process and a patterning process.

12. The display device of claim 1, wherein the louver support layer includes a material different from the first transmissive layer and the second transmissive layer.

13. The display device of claim 12, wherein the louver support layer includes an ester-based compound and a phosphine oxide compound, and
wherein the first transmissive layer and the second transmissive layer include at least one of propylene glycol methyl ether acetate, methacrylic acid-benzylmethacrylic acid copolymer, multi-functional acrylate, or a photo initiator.

14. The display device of claim 13, wherein the louver support layer is formed by an inkjet printing process and a dry etching process, and
wherein the first transmissive layer and the second transmissive layer are formed by a deposition process and a patterning process.

15. The display device of claim 13, further comprising an overcoat layer on the second light blocking layer and the second transmissive layer,
wherein the overcoat layer includes a material different from the louver support layer.

16. The display device of claim 15, wherein the overcoat layer includes at least one of propylene glycol methyl ether acetate, methacrylic acid-benzylmethacrylic acid copolymer, multi-functional acrylate, or a photo initiator.

17. The display device of claim 16, wherein the overcoat layer is formed by a deposition process and a patterning process.

18. A display device comprising:
a substrate;
a light emitting element layer on the substrate and including a plurality of light emitting elements; and
a light control layer on the light emitting element layer,
wherein the light control layer includes:
a first transmissive layer on the light emitting element layer;
a first light blocking layer on the first transmissive layer and including a plurality of light blocking patterns spaced apart from each other;
a second transmissive layer on the first transmissive layer and the first light blocking layer;
a second light blocking layer on the second transmissive layer and including a plurality of light blocking patterns spaced apart from each other; and
wherein a louver layer and a louver support layer on the light emitting element layer and arranged alternately with each other,
wherein the louver layer and the louver support layer are below the first light blocking layer, between the first light blocking layer and the second light blocking layer, or above the second light blocking layer, and
wherein a height of the louver layer is greater than a height of the first light blocking layer and a height of the second light blocking layer.

19. The display device of claim 18, further comprising a light transmissive lower film on the light emitting element layer,
wherein the light transmissive lower film is directly below the first transmissive layer, or directly below the louver layer and the louver support layer.

20. The display device of claim 19, wherein the light transmissive lower film includes a material different from the louver support layer.

21. The display device of claim 20, wherein the louver support layer includes an ester-based compound and a phosphine oxide compound, and
wherein the light transmissive lower film includes at least one of propylene glycol methyl ether acetate, methacrylic acid-benzylmethacrylic acid copolymer, multi-functional acrylate, or a photo initiator.

22. A display device comprising:
a substrate;
a light emitting element layer on the substrate and including a plurality of light emitting elements; and
a light control layer on the light emitting element layer,
wherein the light control layer includes:
a louver layer and a louver support layer on the light emitting element layer and arranged alternately with each other;
a first transmissive layer on the louver layer and the louver support layer;
a first light blocking layer on the first transmissive layer and including a plurality of light blocking patterns spaced apart from each other; and
an optical layer on the louver layer and the louver support layer, or on the first transmissive layer and the first light blocking layer,
a height of the louver layer is greater than a height of the first light blocking layer, and
the optical layer includes a plurality of optical patterns respectively between the plurality of light blocking patterns.

23. The display device of claim 22, wherein the plurality of optical patterns include a converging lens.

24. The display device of claim 23, wherein the plurality of optical patterns include a convex lens that is convex toward a display surface.

25. The display device of claim 23, wherein the plurality of optical patterns include at least one of a lenticular lens array or a micro lens array.

26. The display device of claim 22, wherein each of the plurality of optical patterns at least partially overlaps the plurality of light blocking patterns.

27. The display device of claim 26, wherein a width of each of the plurality of optical patterns is greater than a distance between the plurality of light blocking patterns.

28. The display device of claim 22, wherein each of the plurality of optical patterns does not overlap the plurality of light blocking patterns.

29. The display device of claim 28, wherein a width of each of the plurality of optical patterns is smaller than a distance between the plurality of light blocking patterns.

30. The display device of claim 22, wherein a refractive index of the optical layer is greater than a refractive index of the first transmissive layer and a refractive index of the first light blocking layer.

31. The display device of claim 30, wherein the refractive index of the optical layer is 1.6 or more, and the refractive index of the first transmissive layer and the first light blocking layer are each 1.5 or less.

32. An electronic device comprising a display device, the display device comprising:
a substrate;
a light emitting element layer on the substrate and including a plurality of light emitting elements; and
a light control layer on the light emitting element layer,
wherein the light control layer includes:
a louver layer and a louver support layer on the light emitting element layer and arranged alternately with each other;
a first transmissive layer on the louver layer and the louver support layer;
a first light blocking layer on the first transmissive layer and including a plurality of light blocking patterns spaced apart from each other;
a second transmissive layer on the first transmissive layer and the first light blocking layer; and
a second light blocking layer on the second transmissive layer and including a plurality of light blocking patterns spaced apart from each other, and
wherein a height of the louver layer is greater than a height of the first light blocking layer and a height of the second light blocking layer.

33. An electronic device comprising a display device, the display device comprising:
a substrate;
a light emitting element layer on the substrate and including a plurality of light emitting elements; and
a light control layer on the light emitting element layer,
wherein the light control layer includes:
a first transmissive layer on the light emitting element layer;
a first light blocking layer on the first transmissive layer and including a plurality of light blocking patterns spaced apart from each other;
a second transmissive layer on the first transmissive layer and the first light blocking layer;
a second light blocking layer on the second transmissive layer and including a plurality of light blocking patterns spaced apart from each other; and
wherein a louver layer and a louver support layer on the light emitting element layer and arranged alternately with each other,
wherein the louver layer and the louver support layer are below the first light blocking layer, between the first light blocking layer and the second light blocking layer, or above the second light blocking layer, and
wherein a height of the louver layer is greater than a height of the first light blocking layer and a height of the second light blocking layer.

34. An electronic device comprising a display device, the display device comprising:
a substrate;
a light emitting element layer on the substrate and including a plurality of light emitting elements; and
a light control layer on the light emitting element layer,
wherein the light control layer includes:
a louver layer and a louver support layer on the light emitting element layer and arranged alternately with each other;
a first transmissive layer on the louver layer and the louver support layer;
a first light blocking layer on the first transmissive layer and including a plurality of light blocking patterns spaced apart from each other; and
an optical layer on the louver layer and the louver support layer, or on the first transmissive layer and the first light blocking layer,
a height of the louver layer is greater than a height of the first light blocking layer, and
the optical layer includes a plurality of optical patterns respectively between the plurality of light blocking patterns.
